(19) United States
(12) Patent Application Publication
(10) Pub. No.: US 2025/0141511 A1
(43) Pub. Date: May 1, 2025

(54) SIGNALING WITH UNEQUAL AND FINER MCS

(71) Applicants: Juan Fang, Portland, OR (US); Qinghua Li, San Ramon, CA (US); Shlomi Vituri, Tel Aviv (IL); Assaf Gurevitz, Ramat Hasharon (IL); Hao Song, Santa Clara, CA (US); Thomas J. Kenney, Portland, OR (US); Robert J. Stacey, Portland, OR (US)

(72) Inventors: Juan Fang, Portland, OR (US); Qinghua Li, San Ramon, CA (US); Shlomi Vituri, Tel Aviv (IL); Assaf Gurevitz, Ramat Hasharon (IL); Hao Song, Santa Clara, CA (US); Thomas J. Kenney, Portland, OR (US); Robert J. Stacey, Portland, OR (US)

(21) Appl. No.: 19/011,250

(22) Filed: Jan. 6, 2025

Related U.S. Application Data
(60) Provisional application No. 63/619,692, filed on Jan. 10, 2024.
(60) Provisional application No. 63/667,090, filed on Jul. 2, 2024.

(51) Int. Cl. H04B 7/06; H03M 13/25; H04B 7/0452; H04L 1/00

(52) U.S. Cl. CPC H04B 7/0617; H03M 13/255; H04B 7/0452; H04L 1/0003

(57) ABSTRACT

Methods, apparatuses, and computer readable media for signaling with unequal and finer MCSs, where an apparatus of an AP is configured to: encode a user field for a MU MIMO allocation, the user field comprising a station (STA) identification (ID) (STA-ID) subfield, a modulation and coding scheme (MCS) subfield, a spatial configuration subfield, and a Low-Density Parity Check (LDPC) subfield, the STA-ID subfield identifying a STA associated with the AP. The wireless devices are configured for signaling unequal and finer MCSs, modulation patterns, 2×LDPC, and 1×LDPC.

### PRIORITY CLAIM

This application claims the benefit of priority under 35 USC 119(e) to U.S. Provisional Patent Application Ser. No. 63/619,692, filed Jan. 10, 2024 [reference number AF8820-Z], and U.S. Provisional Patent Application Ser. No. 63/667,090, filed Jul. 2, 2024 [reference number AG2312-Z] both of which are incorporated herein by reference in its entirety.

### TECHNICAL FIELD

Embodiments relate to signaling with unequal modulation and coding schemes (MSC) and finer MSCs, in accordance with wireless local area networks (WLANs) and Wi-Fi networks including networks operating in accordance with different versions or generations of the IEEE 802.11 family of standards.

### BACKGROUND

Efficient use of the resources of a wireless local-area network (WLAN) is important to provide bandwidth and acceptable response times to the users of the WLAN. However, often there are many devices trying to share the same resources and the wireless medium may be noisy. Moreover, wireless devices may need to operate with both newer protocols and with legacy device protocols on different bands and on different channels.

### BRIEF DESCRIPTION OF THE DRAWINGS

The present disclosure is illustrated by way of example and not limitation in the figures of the accompanying drawings, in which like references indicate similar elements and in which:

FIG. 1 is a block diagram of a radio architecture in accordance with some embodiments;

FIG. 2 illustrates a front-end module circuitry for use in the radio architecture of FIG. 1 in accordance with some embodiments;

FIG. 3 illustrates a radio IC circuitry for use in the radio architecture of FIG. 1 in accordance with some embodiments;

FIG. 4 illustrates a baseband processing circuitry for use in the radio architecture of FIG. 1 in accordance with some embodiments;

FIG. 5 illustrates a WLAN in accordance with some embodiments;

FIG. 6 illustrates a block diagram of an example machine upon which any one or more of the techniques (e.g., methodologies) discussed herein may perform;

FIG. 7 illustrates a block diagram of an example wireless device upon which any one or more of the techniques (e.g., methodologies or operations) discussed herein may perform;

FIG. 8 illustrates multi-link devices (MLD) s, in accordance with some embodiments;

FIG. 9 illustrates a user field field, in accordance with some embodiments;

FIG. 10 illustrates a user field, in accordance with some embodiments;

FIG. 11 illustrates a UHR user field, in accordance with some embodiments;

FIG. 12 illustrates a UHR user field, in accordance with some embodiments;

FIG. 13 illustrates a user field, in accordance with some embodiments;

FIG. 14 illustrates a user field, in accordance with some embodiments;

FIG. 15 illustrates a user field, in accordance with some embodiments;

FIG. 16 illustrates an UHR user info field, in accordance with some embodiments;

FIG. 17 illustrates an UHR user info field, in accordance with some embodiments;

FIG. 18 illustrates UHR user field, in accordance with some embodiments;

FIG. 19 illustrates a method for signaling with unequal and finer MCSs, in accordance with some embodiments;

FIG. 20 illustrates a method for signaling with unequal and finer MCSs, in accordance with some embodiments.

### DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

FIG. 1 is a block diagram of a radio architecture 100 in accordance with some embodiments. Radio architecture 100 may include radio front-end module (FEM) circuitry 104, radio IC circuitry 106 and baseband processing circuitry 108. Radio architecture 100 as shown includes both Wireless Local Area Network (WLAN) functionality and Bluetooth® (BT) functionality although embodiments are not so limited. In this disclosure, “WLAN” and “Wi-Fi” are used interchangeably.

FEM circuitry 104 may include a WLAN or Wi-Fi FEM circuitry 104A and a Bluetooth® (BT) FEM circuitry 104B. The WLAN FEM circuitry 104A may include a receive signal path comprising circuitry configured to operate on WLAN RF signals received from one or more antennas 101, to amplify the received signals and to provide the amplified versions of the received signals to the WLAN radio IC circuitry 106A for further processing. The BT FEM circuitry 104B may include a receive signal path which may include circuitry configured to operate on BT RF signals received from one or more antennas 101, to amplify the received signals and to provide the amplified versions of the received signals to the BT radio IC circuitry 106B for further processing. FEM circuitry 104A may also include a transmit signal path which may include circuitry configured to amplify WLAN signals provided by the radio IC circuitry 106A for wireless transmission by one or more of the antennas 101. In addition, FEM circuitry 104B may also include a transmit signal path which may include circuitry configured to amplify BT signals provided by the radio IC circuitry 106B for wireless transmission by the one or more antennas. In the embodiment of FIG. 1, although FEM circuitry 104A and FEM circuitry 104B are shown as being distinct from one another, embodiments are not so limited, and include within their scope the use of an FEM (not shown) that includes a transmit path and/or a receive path for both WLAN and BT signals, or the use of one or more FEM circuitries where at least some of the FEM circuitries share transmit and/or receive signal paths for both WLAN and BT signals.

Radio IC circuitry 106 as shown may include WLAN radio IC circuitry 106A and BT radio IC circuitry 106B. The WLAN radio IC circuitry 106A may include a receive signal path which may include circuitry to down-convert WLAN RF signals received from the FEM circuitry 104A and provide baseband signals to WLAN baseband processing circuitry 108A. BT radio IC circuitry 106B may in turn include a receive signal path which may include circuitry to down-convert BT RF signals received from the FEM circuitry 104B and provide baseband signals to BT baseband processing circuitry 108B. WLAN radio IC circuitry 106A may also include a transmit signal path which may include circuitry to up-convert WLAN baseband signals provided by the WLAN baseband processing circuitry 108A and provide WLAN RF output signals to the FEM circuitry 104A for subsequent wireless transmission by the one or more antennas 101. BT radio IC circuitry 106B may also include a transmit signal path which may include circuitry to up-convert BT baseband signals provided by the BT baseband processing circuitry 108B and provide BT RF output signals to the FEM circuitry 104B for subsequent wireless transmission by the one or more antennas 101. In the embodiment of FIG. 1, although radio IC circuitries 106A and 106B are shown as being distinct from one another, embodiments are not so limited, and include within their scope the use of a radio IC circuitry (not shown) that includes a transmit signal path and/or a receive signal path for both WLAN and BT signals, or the use of one or more radio IC circuitries where at least some of the radio IC circuitries share transmit and/or receive signal paths for both WLAN and BT signals.

Baseband processing circuitry 108 may include a WLAN baseband processing circuitry 108A and a BT baseband processing circuitry 108B. The WLAN baseband processing circuitry 108A may include a memory, such as, for example, a set of RAM arrays in a Fast Fourier Transform or Inverse Fast Fourier Transform block (not shown) of the WLAN baseband processing circuitry 108A. Each of the WLAN baseband processing circuitry 108A and the BT baseband circuitry 108B may further include one or more processors and control logic to process the signals received from the corresponding WLAN or BT receive signal path of the radio IC circuitry 106, and to also generate corresponding WLAN or BT baseband signals for the transmit signal path of the radio IC circuitry 106. Each of the baseband processing circuitries 108A and 108B may further include physical layer (PHY) and medium access control layer (MAC) circuitry, and may further interface with application processor 111 for generation and processing of the baseband signals and for controlling operations of the radio IC circuitry 106.

Referring still to FIG. 1, according to the shown embodiment, WLAN-BT coexistence circuitry 113 may include logic providing an interface between the WLAN baseband processing circuitry 108A and the BT baseband circuitry 108B to enable use cases requiring WLAN and BT coexistence. In addition, a switch 103 may be provided between the WLAN FEM circuitry 104A and the BT FEM circuitry 104B to allow switching between the WLAN and BT radios according to application needs. In addition, although the antennas 101 are depicted as being respectively connected to the WLAN FEM circuitry 104A and the BT FEM circuitry 104B, embodiments include within their scope the sharing of one or more antennas as between the WLAN and BT FEMs, or the provision of more than one antenna connected to each of FEM circuitry 104A or FEM circuitry 104B.

In some embodiments, the front-end module circuitry 104, the radio IC circuitry 106, and baseband processing circuitry 108 may be provided on a single radio card, such as wireless radio card 102. In some other embodiments, the one or more antennas 101, the FEM circuitry 104 and the radio IC circuitry 106 may be provided on a single radio card. In some other embodiments, the radio IC circuitry 106 and the baseband processing circuitry 108 may be provided on a single chip or IC, such as IC 112.

In some embodiments, the wireless radio card 102 may include a WLAN radio card and may be configured for Wi-Fi communications, although the scope of the embodiments is not limited in this respect. In some of these embodiments, the radio architecture 100 may be configured to receive and transmit orthogonal frequency division multiplexed (OFDM) or orthogonal frequency division multiple access (OFDMA) communication signals over a multicarrier communication channel. The OFDM or OFDMA signals may comprise a plurality of orthogonal subcarriers.

In some of these multicarrier embodiments, radio architecture 100 may be part of a Wi-Fi communication station (STA) such as a wireless access point (AP), a base station or a mobile device including a Wi-Fi device. In some of these embodiments, radio architecture 100 may be configured to transmit and receive signals in accordance with specific communication standards and/or protocols, such as any of the Institute of Electrical and Electronics Engineers (IEEE) standards including, IEEE 802.11n-2009, IEEE 802.11-2012, IEEE 802.11-2016, IEEE 802.11ac, and/or IEEE 802.11ax standards and/or proposed specifications for WLANs, although the scope of embodiments is not limited in this respect. Radio architecture 100 may also be suitable to transmit and/or receive communications in accordance with other techniques and standards.

In some embodiments, the radio architecture 100 may be configured for high-efficiency (HE) Wi-Fi (HEW) communications in accordance with the IEEE 802.11ax standard. In these embodiments, the radio architecture 100 may be configured to communicate in accordance with an OFDMA technique, although the scope of the embodiments is not limited in this respect.

In some other embodiments, the radio architecture 100 may be configured to transmit and receive signals transmitted using one or more other modulation techniques such as spread spectrum modulation (e.g., direct sequence code division multiple access (DS-CDMA) and/or frequency hopping code division multiple access (FH-CDMA)), time-division multiplexing (TDM) modulation, and/or frequency-division multiplexing (FDM) modulation, although the scope of the embodiments is not limited in this respect.

In some embodiments, as further shown in FIG. 1, the BT baseband circuitry 108B may be compliant with a Bluetooth® (BT) connectivity standard such as Bluetooth®, Bluetooth® 4.0 or Bluetooth® 5.0, or any other iteration of the Bluetooth® Standard. In embodiments that include BT functionality as shown for example in FIG. 1, the radio architecture 100 may be configured to establish a BT synchronous connection oriented (SCO) link and/or a BT low energy (BT LE) link. In some of the embodiments that include functionality, the radio architecture 100 may be configured to establish an extended SCO (eSCO) link for BT communications, although the scope of the embodiments is not limited in this respect. In some of these embodiments that include a BT functionality, the radio architecture may be configured to engage in a BT Asynchronous Connection-Less (ACL) communications, although the scope of the embodiments is not limited in this respect. In some embodiments, as shown in FIG. 1, the functions of a BT radio card and WLAN radio card may be combined on a single wireless radio card, such as single wireless radio card 102, although embodiments are not so limited, and include within their scope discrete WLAN and BT radio cards

In some embodiments, the radio architecture 100 may include other radio cards, such as a cellular radio card configured for cellular (e.g., 3GPP such as LTE, LTE-Advanced or 5G communications).

In some IEEE 802.11 embodiments, the radio architecture 100 may be configured for communication over various channel bandwidths including bandwidths having center frequencies of about nine hundred MHz, 2.4 GHz, 5 GHz, and bandwidths of about 1 MHz, 2 MHz, 2.5 MHz, 4 MHz, 5 MHz, 8 MHz, 10 MHz, 16 MHz, 20 MHz, 40 MHz, 80 MHz (with contiguous bandwidths) or 80+80 MHz (160 MHz) (with non-contiguous bandwidths). In some embodiments, a 320 MHz channel bandwidth may be used. The scope of the embodiments is not limited with respect to the above center frequencies however.

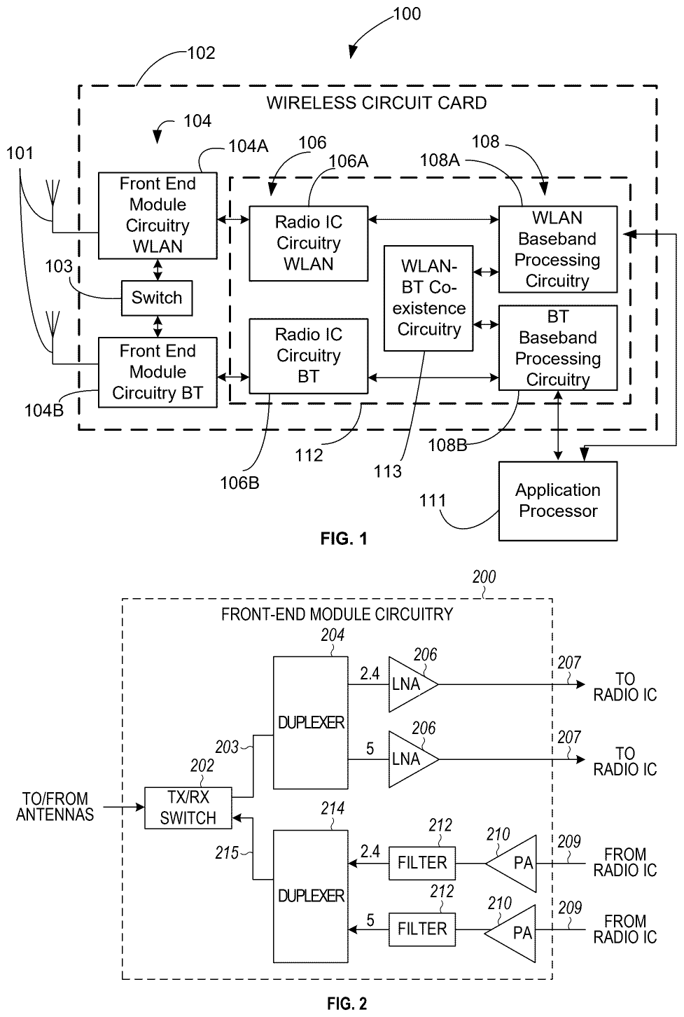

FIG. 2 illustrates FEM circuitry 200 in accordance with some embodiments. The FEM circuitry 200 is one example of circuitry that may be suitable for use as the WLAN and/or BT FEM circuitry 104A/104B (FIG. 1), although other circuitry configurations may also be suitable.

In some embodiments, the FEM circuitry 200 may include a TX/RX switch 202 to switch between transmit mode and receive mode operation. The FEM circuitry 200 may include a receive signal path and a transmit signal path. The receive signal path of the FEM circuitry 200 may include a low-noise amplifier (LNA) 206 to amplify received RF signals 203 and provide the amplified received RF signals 207 as an output (e.g., to the radio IC circuitry 106 (FIG. 1)). The transmit signal path of the circuitry 200 may include a power amplifier (PA) to amplify input RF signals 209 (e.g., provided by the radio IC circuitry 106), and one or more filters 212, such as band-pass filters (BPFs), low-pass filters (LPFs) or other types of filters, to generate RF signals 215 for subsequent transmission (e.g., by one or more of the antennas 101 (FIG. 1)).

In some dual-mode embodiments for Wi-Fi communication, the FEM circuitry 200 may be configured to operate in either the 2.4 GHz frequency spectrum or the 5 GHz frequency spectrum. In these embodiments, the receive signal path of the FEM circuitry 200 may include a receive signal path duplexer 204 to separate the signals from each spectrum as well as provide a separate LNA 206 for each spectrum as shown. In these embodiments, the transmit signal path of the FEM circuitry 200 may also include a power amplifier 210 and a filter 212, such as a BPF, a LPF or another type of filter for each frequency spectrum and a transmit signal path duplexer 214 to provide the signals of one of the different spectrums onto a single transmit path for subsequent transmission by the one or more of the antennas 101 (FIG. 1). In some embodiments, BT communications may utilize the 2.4 GHz signal paths and may utilize the same FEM circuitry 200 as the one used for WLAN communications.

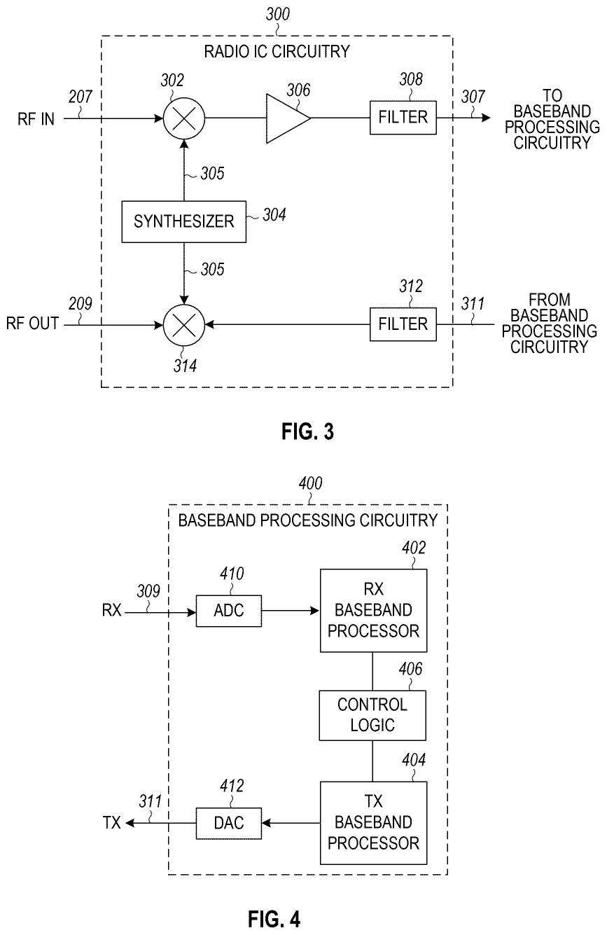

FIG. 3 illustrates radio integrated circuit (IC) circuitry 300 in accordance with some embodiments. The radio IC circuitry 300 is one example of circuitry that may be suitable for use as the WLAN or BT radio IC circuitry 106A/106B (FIG. 1), although other circuitry configurations may also be suitable.

In some embodiments, the radio IC circuitry 300 may include a receive signal path and a transmit signal path. The receive signal path of the radio IC circuitry 300 may include at least mixer circuitry 302, such as, for example, down-conversion mixer circuitry, amplifier circuitry 306 and filter circuitry 308. The transmit signal path of the radio IC circuitry 300 may include at least filter circuitry 312 and mixer circuitry 314, such as, for example, up-conversion mixer circuitry. Radio IC circuitry 300 may also include synthesizer circuitry 304 for synthesizing a frequency 305 for use by the mixer circuitry 302 and the mixer circuitry 314. The mixer circuitry 302 and/or 314 may each, according to some embodiments, be configured to provide direct conversion functionality. The latter type of circuitry presents a much simpler architecture as compared with standard super-heterodyne mixer circuitries, and any flicker noise brought about by the same may be alleviated for example through the use of OFDM modulation. FIG. 3 illustrates only a simplified version of a radio IC circuitry, and may include, although not shown, embodiments where each of the depicted circuitries may include more than one component. For instance, mixer circuitry 302 and/or 314 may each include one or more mixers, and filter circuitries 308 and/or 312 may each include one or more filters, such as one or more BPFs and/or LPFs according to application needs. For example, when mixer circuitries are of the direct-conversion type, they may each include two or more mixers.

In some embodiments, mixer circuitry 302 may be configured to down-convert RF signals 207 received from the FEM circuitry 104 (FIG. 1) based on the synthesized frequency 305 provided by synthesizer circuitry 304. The amplifier circuitry 306 may be configured to amplify the down-converted signals and the filter circuitry 308 may include a LPF configured to remove unwanted signals from the down-converted signals to generate output baseband signals 307. Output baseband signals 307 may be provided to the baseband processing circuitry 108 (FIG. 1) for further processing. In some embodiments, the output baseband signals 307 may be zero-frequency baseband signals, although this is not a requirement. In some embodiments, mixer circuitry 302 may comprise passive mixers, although the scope of the embodiments is not limited in this respect.

In some embodiments, the mixer circuitry 314 may be configured to up-convert input baseband signals 311 based on the synthesized frequency 305 provided by the synthesizer circuitry 304 to generate RF output signals 209 for the FEM circuitry 104. The baseband signals 311 may be provided by the baseband processing circuitry 108 and may be filtered by filter circuitry 312. The filter circuitry 312 may include a LPF or a BPF, although the scope of the embodiments is not limited in this respect.

In some embodiments, the mixer circuitry 302 and the mixer circuitry 314 may each include two or more mixers and may be arranged for quadrature down-conversion and/or up-conversion respectively with the help of synthesizer circuitry 304. In some embodiments, the mixer circuitry 302 and the mixer circuitry 314 may each include two or more mixers each configured for image rejection (e.g., Hartley image rejection). In some embodiments, the mixer circuitry 302 and the mixer circuitry 314 may be arranged for direct down-conversion and/or direct up-conversion, respectively. In some embodiments, the mixer circuitry 302 and the mixer circuitry 314 may be configured for super-heterodyne operation, although this is not a requirement.

Mixer circuitry 302 may comprise, according to one embodiment: quadrature passive mixers (e.g., for the in-phase (I) and quadrature phase (Q) paths). In such an embodiment, RF input signal 207 from FIG. 3 may be down-converted to provide I and Q baseband output signals to be sent to the baseband processor

Quadrature passive mixers may be driven by zero and ninety-degree time-varying LO switching signals provided by a quadrature circuitry which may be configured to receive a LO frequency (f_{LO}) from a local oscillator or a synthesizer, such as LO frequency 305 of synthesizer circuitry 304 (FIG. 3). In some embodiments, the LO frequency may be the carrier frequency, while in other embodiments, the LO frequency may be a fraction of the carrier frequency (e.g., one-half the carrier frequency, one-third the carrier frequency). In some embodiments, the zero and ninety-degree time-varying switching signals may be generated by the synthesizer, although the scope of the embodiments is not limited in this respect.

In some embodiments, the LO signals may differ in duty cycle (the percentage of one period in which the LO signal is high) and/or offset (the difference between start points of the period). In some embodiments, the LO signals may have a 25% duty cycle and a 50% offset. In some embodiments, each branch of the mixer circuitry (e.g., the in-phase (I) and quadrature phase (Q) path) may operate at a 25% duty cycle, which may result in a significant reduction is power consumption.

The RF input signal 207 (FIG. 2) may comprise a balanced signal, although the scope of the embodiments is not limited in this respect. The I and Q baseband output signals may be provided to low-nose amplifier, such as amplifier circuitry 306 (FIG. 3) or to filter circuitry 308 (FIG. 3).

In some embodiments, the output baseband signals 307 and the input baseband signals 311 may be analog baseband signals, although the scope of the embodiments is not limited in this respect. In some alternate embodiments, the output baseband signals 307 and the input baseband signals 311 may be digital baseband signals. In these alternate embodiments, the radio IC circuitry may include analog-to-digital converter (ADC) and digital-to-analog converter (DAC) circuitry.

In some dual-mode embodiments, a separate radio IC circuitry may be provided for processing signals for each spectrum, or for other spectrums not mentioned here, although the scope of the embodiments is not limited in this respect.

In some embodiments, the synthesizer circuitry 304 may be a fractional-N synthesizer or a fractional N/N+1 synthesizer, although the scope of the embodiments is not limited in this respect as other types of frequency synthesizers may be suitable. For example, synthesizer circuitry 304 may be a delta-sigma synthesizer, a frequency multiplier, or a synthesizer comprising a phase-locked loop with a frequency divider. According to some embodiments, the synthesizer circuitry 304 may include digital synthesizer circuitry. An advantage of using a digital synthesizer circuitry is that, although it may still include some analog components, its footprint may be scaled down much more than the footprint of an analog synthesizer circuitry. In some embodiments, frequency input into synthesizer circuitry 304 may be provided by a voltage controlled oscillator (VCO), although that is not a requirement. A divider control input may further be provided by either the baseband processing circuitry 108 (FIG. 1) or the application processor 111 (FIG. 1) depending on the desired output frequency 305. In some embodiments, a divider control input (e.g., N) may be determined from a look-up table (e.g., within a Wi-Fi card) based on a channel number and a channel center frequency as determined or indicated by the application processor 111.

In some embodiments, synthesizer circuitry 304 may be configured to generate a carrier frequency as the output frequency 305, while in other embodiments, the output frequency 305 may be a fraction of the carrier frequency (e.g., one-half the carrier frequency, one-third the carrier frequency). In some embodiments, the output frequency 305 may be a LO frequency (f_{LO}).

FIG. 4 illustrates a functional block diagram of baseband processing circuitry 400 in accordance with some embodiments. The baseband processing circuitry 400 is one example of circuitry that may be suitable for use as the baseband processing circuitry 108 (FIG. 1), although other circuitry configurations may also be suitable. The baseband processing circuitry 400 may include a receive baseband processor (RX BBP) 402 for processing receive baseband signals 309 provided by the radio IC circuitry 106 (FIG. 1) and a transmit baseband processor (TX BBP) 404 for generating transmit baseband signals 311 for the radio IC circuitry 106. The baseband processing circuitry 400 may also include control logic 406 for coordinating the operations of the baseband processing circuitry 400.

In some embodiments (e.g., when analog baseband signals are exchanged between the baseband processing circuitry 400 and the radio IC circuitry 106), the baseband processing circuitry 400 may include ADC 410 to convert analog baseband signals received from the radio IC circuitry 106 to digital baseband signals for processing by the RX BBP 402. In these embodiments, the baseband processing circuitry 400 may also include DAC 412 to convert digital baseband signals from the TX BBP 404 to analog baseband signals.

In some embodiments that communicate OFDM signals or OFDMA signals, such as through baseband processing circuitry 108A, the TX BBP 404 may be configured to generate OFDM or OFDMA signals as appropriate for transmission by performing an inverse fast Fourier transform (IFFT). The RX BBP 402 may be configured to process received OFDM signals or OFDMA signals by performing an FFT. In some embodiments, the RX BBP 402 may be configured to detect the presence of an OFDM signal or OFDMA signal by performing an autocorrelation, to detect a preamble, such as a short preamble, and by performing a cross-correlation, to detect a long preamble. The preambles may be part of a predetermined frame structure for Wi-Fi communication.

Referring to FIG. 1, in some embodiments, the antennas 101 (FIG. 1) may each comprise one or more directional or omnidirectional antennas, including, for example, dipole antennas, monopole antennas, patch antennas, loop antennas, microstrip antennas or other types of antennas suitable for transmission of RF signals. In some multiple-input multiple-output (MIMO) embodiments, the antennas may be effectively separated to take advantage of spatial diversity and the different channel characteristics that may result. Antennas 101 may each include a set of phased-array antennas, although embodiments are not so limited.

Although the radio architecture 100 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, field-programmable gate arrays (FPGAs), application specific integrated circuits (ASICs), radio-frequency integrated circuits (RFICs) and combinations of various hardware and logic circuitry for performing at least the functions described herein. In some embodiments, the functional elements may refer to one or more processes operating on one or more processing elements.

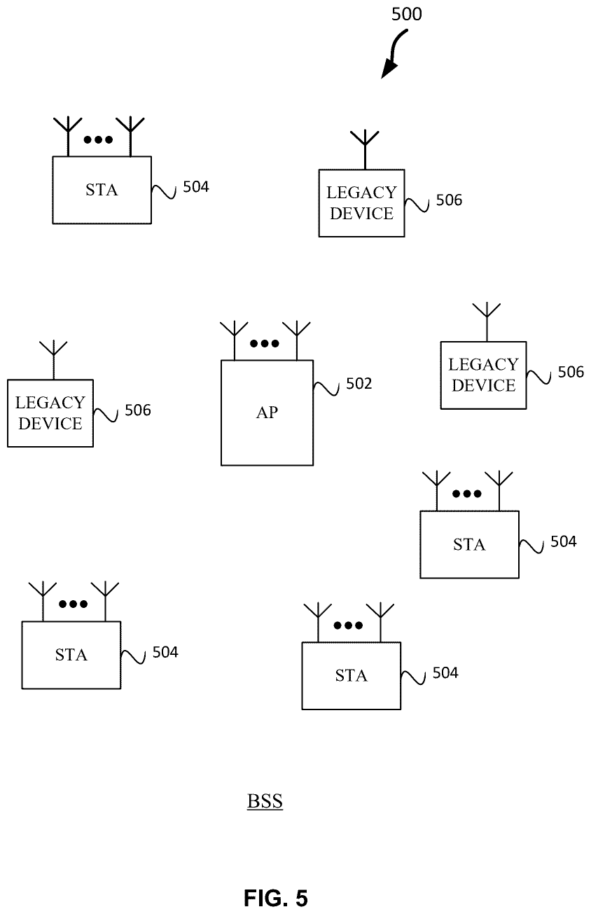

FIG. 5 illustrates a WLAN 500 in accordance with some embodiments. The WLAN 500 may comprise a basis service set (BSS) that may include an access point (AP) AP 502, a plurality of stations (STAs) STAs 504, and a plurality of legacy devices 506. In some embodiments, the STAs 504 and/or AP 502 are configured to operate in accordance with IEEE 802.11be extremely high throughput (EHT), WiFi 8 IEEE 802.11 ultra-high throughput (UHT), high efficiency (HE) IEEE 802.11ax, IEEE 802.11bn next generation, Ultra High Reliability (UHR)/802.11bn/Wi-Fi 8, and/or another IEEE 802.11 wireless communication standard. In some embodiments, the STAs 504 and/or AP 502 are configured to operate in accordance with IEEE P802.11be, and/or IEEE P802.11-REVme™, both of which are hereby included by reference in their entirety.

The AP 502 may use other communications protocols as well as the IEEE 802.11 protocol. The terms here may be termed differently in accordance with some embodiments. The IEEE 802.11 protocol may include using orthogonal frequency division multiple-access (OFDMA), time division multiple access (TDMA), and/or code division multiple access (CDMA). The IEEE 802.11 protocol may include a multiple access technique. For example, the IEEE 802.11 protocol may include space-division multiple access (SDMA) and/or multiple-user multiple-input multiple-output (MU-MIMO). There may be more than one AP 502 that is part of an extended service set (ESS). A controller (not illustrated) may store information that is common to the more than one APs 502 and may control more than one BSS, e.g., assign primary channels, colors, etc. AP 502 may be connected to the internet.

The legacy devices 506 may operate in accordance with one or more of IEEE 802.11 a/b/g/n/ac/ad/af/ah/aj/ay/ax/uht, or another legacy wireless communication standard. The legacy devices 506 may be STAs or IEEE STAs. The STAs 504 may be wireless transmit and receive devices such as cellular telephone, portable electronic wireless communication devices, smart telephone, handheld wireless device, wireless glasses, wireless watch, wireless personal device, tablet, or another device that may be transmitting and receiving using the IEEE 802.11 protocol such as IEEE 802.11be or another wireless protocol.

The AP 502 may communicate with legacy devices 506 in accordance with legacy IEEE 802.11 communication techniques. In example embodiments, the AP 502 may also be configured to communicate with STAs 504 in accordance with legacy IEEE 802.11 communication techniques.

In some embodiments, a HE, EHT, UHT frames may be configurable to have the same bandwidth as a channel. The HE, EHT, UHT frame may be a physical Layer Convergence Procedure (PLCP) Protocol Data Unit (PPDU). In some embodiments, PPDU may be an abbreviation for physical layer protocol data unit (PPDU). In some embodiments, there may be different types of PPDUs that may have different fields and different physical layers and/or different media access control (MAC) layers. For example, a single user (SU) PPDU, downlink (DL) PPDU, multiple-user (MU) PPDU, extended-range (ER) SU PPDU, and/or trigger-based (TB) PPDU. In some embodiments EHT may be the same or similar as HE PPDUs.

The bandwidth of a channel may be 20 MHz, 40 MHz, or 80 MHz, 80+80 MHz, 160 MHz, 160+160 MHz, 320 MHz, 320+320 MHz, 640 MHz bandwidths. In some embodiments, the bandwidth of a channel less than 20 MHz may be 1 MHz, 1.25 MHz, 2.03 MHz, 2.5 MHz, 4.06 MHz, 5 MHz and 10 MHz, or a combination thereof or another bandwidth that is less or equal to the available bandwidth may also be used. In some embodiments the bandwidth of the channels may be based on a number of active data subcarriers. In some embodiments the bandwidth of the channels is based on 26, 52, 106, 242, 484, 996, or 2×996 active data subcarriers or tones that are spaced by 20 MHz. In some embodiments the bandwidth of the channels is 256 tones spaced by 20 MHz. In some embodiments the channels are multiple of 26 tones or a multiple of 20 MHz. In some embodiments a 20 MHz channel may comprise 242 active data subcarriers or tones, which may determine the size of a Fast Fourier Transform (FFT). An allocation of a bandwidth or a number of tones or sub-carriers may be termed a resource unit (RU) allocation in accordance with some embodiments.

In some embodiments, the 26-subcarrier RU and 52-subcarrier RU are used in the 20 MHz, 40 MHz, 80 MHz, 160 MHz and 80+80 MHz OFDMA HE PPDU formats. In some embodiments, the 106-subcarrier RU is used in the 20 MHz, 40 MHz, 80 MHz, 160 MHz and 80+80 MHz OFDMA and MU-MIMO HE PPDU formats. In some embodiments, the 242-subcarrier RU is used in the 40 MHz, 80 MHz, 160 MHz and 80+80 MHz OFDMA and MU-MIMO HE PPDU formats. In some embodiments, the 484-subcarrier RU is used in the 80 MHz, 160 MHz and 80+80 MHz OFDMA and MU-MIMO HE PPDU formats. In some embodiments, the 996-subcarrier RU is used in the 160 MHz and 80+80 MHz OFDMA and MU-MIMO HE PPDU formats.

A HE, EHT, UHT, UHT, or UHR frame may be configured for transmitting a number of spatial streams, which may be in accordance with MU-MIMO and may be in accordance with OFDMA. In other embodiments, the AP 502, STA 504, and/or legacy device 506 may also implement different technologies such as code division multiple access (CDMA) 2000, CDMA 2000 1×, CDMA 2000 Evolution-Data Optimized (EV-DO), Interim Standard 2000 (IS-2000), Interim Standard 95 (IS-95), Interim Standard 856 (IS-856), Long Term Evolution (LTE), Global System for Mobile communications (GSM), Enhanced Data rates for GSM Evolution (EDGE), GSM EDGE (GERAN), IEEE 802.16 (i.e., Worldwide Interoperability for Microwave Access (WiMAX)), Bluetooth®, low-power Bluetooth®, or other technologies.

In accordance with some IEEE 802.11 embodiments, e.g., IEEE 802.11EHT/ax/be embodiments, a HE AP 502 may operate as a master station which may be arranged to contend for a wireless medium (e.g., during a contention period) to receive exclusive control of the medium for a transmission opportunity (TXOP). The AP 502 may transmit an EHT/HE trigger frame transmission, which may include a schedule for simultaneous UL/DL transmissions from STAs 504. The AP 502 may transmit a time duration of the TXOP and sub-channel information. During the TXOP, STAs 504 may communicate with the AP 502 in accordance with a non-contention based multiple access technique such as OFDMA or MU-MIMO. This is unlike conventional WLAN communications in which devices communicate in accordance with a contention-based communication technique, rather than a multiple access technique. During the HE, EHT, UHR control period, the AP 502 may communicate with STAs 504 using one or more HE or EHT frames. During the TXOP, the HE STAs 504 may operate on a sub-channel smaller than the operating range of the AP 502. During the TXOP, legacy stations refrain from communicating. The legacy stations may need to receive the communication from the HE AP 502 to defer from communicating.

In accordance with some embodiments, during the TXOP the STAs 504 may contend for the wireless medium with the legacy devices 506 being excluded from contending for the wireless medium during the master-sync transmission. In some embodiments the trigger frame may indicate an UL-MU-MIMO and/or UL OFDMA TXOP. In some embodiments, the trigger frame may include a DL UL-MU-MIMO and/or DL OFDMA with a schedule indicated in a preamble portion of trigger frame.

In some embodiments, the multiple-access technique used during the HE or EHT TXOP may be a scheduled OFDMA technique, although this is not a requirement. In some embodiments, the multiple access technique may be a time-division multiple access (TDMA) technique or a frequency division multiple access (FDMA) technique. In some embodiments, the multiple access technique may be a space-division multiple access (SDMA) technique. In some embodiments, the multiple access technique may be a Code division multiple access (CDMA).

The AP 502 may also communicate with legacy devices 506 and/or STAs 504 in accordance with legacy IEEE 802.11 communication techniques. In some embodiments, the AP 502 may also be configurable to communicate with STAs 504 outside the TXOP in accordance with legacy IEEE 802.11 or IEEE 802.11EHT/UHR communication techniques, although this is not a requirement.

In some embodiments the STA 504 may be a “group owner” (GO) for peer-to-peer modes of operation. A wireless device may be a STA 504 or a HE AP 502. The STA 504 may be termed a non-access point (AP) (non-AP) STA 504, in accordance with some embodiments.

In some embodiments, the STA 504 and/or AP 502 may be configured to operate in accordance with IEEE 802.11mc. In example embodiments, the radio architecture of FIG. 1 is configured to implement the STA 504 and/or the AP 502. In example embodiments, the front-end module circuitry of FIG. 2 is configured to implement the STA 504 and/or the AP 502. In example embodiments, the radio IC circuitry of FIG. 3 is configured to implement the HE STA 504 and/or the AP 502. In example embodiments, the base-band processing circuitry of FIG. 4 is configured to implement the STA 504 and/or the AP 502.

In example embodiments, the STAs 504, AP 502, an apparatus of the STA 504, and/or an apparatus of the AP 502 may include one or more of the following: the radio architecture of FIG. 1, the front-end module circuitry of FIG. 2, the radio IC circuitry of FIG. 3, and/or the base-band processing circuitry of FIG. 4.

In example embodiments, the radio architecture of FIG. 1, the front-end module circuitry of FIG. 2, the radio IC circuitry of FIG. 3, and/or the base-band processing circuitry of FIG. 4 may be configured to perform the methods and operations/functions herein described in conjunction with FIGS. 1-20.

In example embodiments, the STAs 504 and/or the AP 502 are configured to perform the methods and operations/functions described herein in conjunction with FIGS. 1-20. In example embodiments, an apparatus of the STA 504 and/or an apparatus of the AP 502 are configured to perform the methods and functions described herein in conjunction with FIGS. 1-20. The term Wi-Fi may refer to one or more of the IEEE 802.11 communication standards. AP and STA may refer to EHT/HE access point and/or EHT/HE station as well as legacy devices 506.

In some embodiments, a HE AP STA may refer to an AP 502 and/or STAs 504 that are operating as EHT APs 502. In some embodiments, when a STA 504 is not operating as an AP, it may be referred to as a non-AP STA or non-AP. In some embodiments, STA 504 may be referred to as either an AP STA or a non-AP. The AP 502 may be part of, or affiliated with, an AP MLD 808, e.g., AP1 830, AP2 832, or AP3 834. The STAs 504 may be part of, or affiliated with, a non-AP MLD 809, which may be termed a ML non-AP logical entity. The BSS may be part of an extended service set (ESS), which may include multiple APs, access to the internet, and may include one or more management devices.

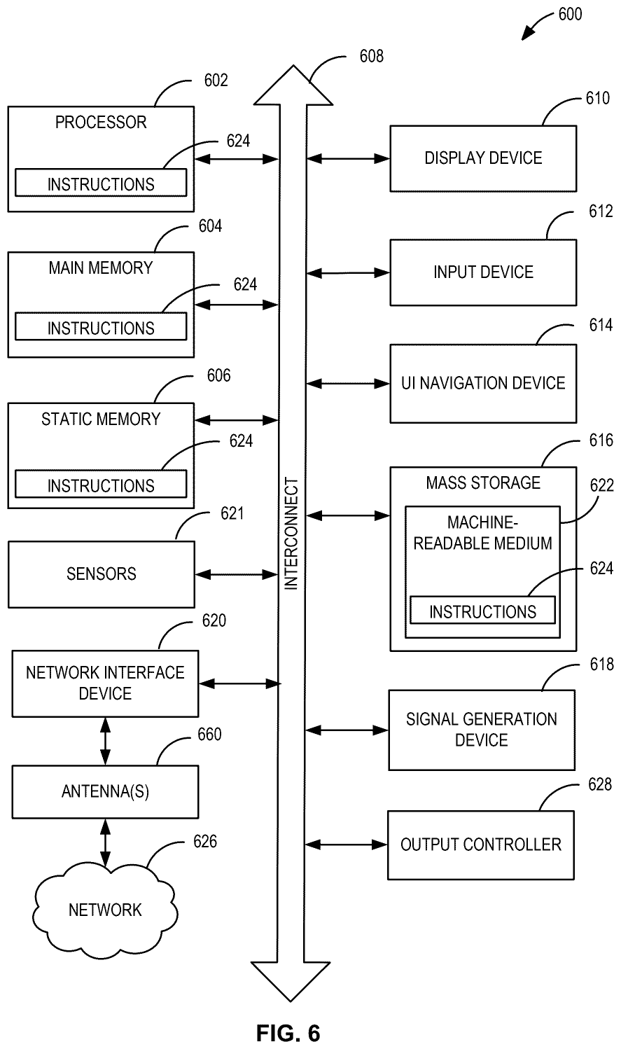

FIG. 6 illustrates a block diagram of an example machine 600 upon which any one or more of the techniques (e.g., methodologies) discussed herein may perform. In alternative embodiments, the machine 600 may operate as a standalone device or may be connected (e.g., networked) to other machines. In a networked deployment, the machine 600 may operate in the capacity of a server machine, a client machine, or both in server-client network environments. In an example, the machine 600 may act as a peer machine in peer-to-peer (P2P) (or other distributed) network environment. The machine 600 may be a HE AP 502, EVT STA 504, personal computer (PC), a tablet PC, a set-top box (STB), a personal digital assistant (PDA), a portable communications device, a mobile telephone, a smart phone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Machine (e.g., computer system) 600 may include a hardware processor 602 (e.g., a central processing unit (CPU), a graphics processing unit (GPU), a hardware processor core, or any combination thereof), a main memory 604 and a static memory 606, some or all of which may communicate with each other via an interlink (e.g., bus) 608.

Specific examples of main memory 604 include Random Access Memory (RAM), and semiconductor memory devices, which may include, in some embodiments, storage locations in semiconductors such as registers. Specific examples of static memory 606 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

The machine 600 may further include a display device 610, an input device 612 (e.g., a keyboard), and a user interface (UI) navigation device 614 (e.g., a mouse). In an example, the display device 610, input device 612 and UI navigation device 614 may be a touch screen display. The machine 600 may additionally include a mass storage (e.g., drive unit) 616, a signal generation device 618 (e.g., a speaker), a network interface device 620, and one or more sensors 621, such as a global positioning system (GPS) sensor, compass, accelerometer, or other sensor. The machine 600 may include an output controller 628, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments the processor 602 and/or instructions 624 may comprise processing circuitry and/or transceiver circuitry.

The mass storage 616 device may include a machine readable medium 622 on which is stored one or more sets of data structures or instructions 624 (e.g., software) embodying or utilized by any one or more of the techniques or functions described herein. The instructions 624 may also reside, completely or at least partially, within the main memory 604, within static memory 606, or within the hardware processor 602 during execution thereof by the machine 600. In an example, one or any combination of the hardware processor 602, the main memory 604, the static memory 606, or the mass storage 616 device may constitute machine readable media.

Specific examples of machine-readable media may include: non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine readable medium 622 is illustrated as a single medium, the term “machine readable medium” may include a single medium or multiple media (e.g., a centralized or distributed database, and/or associated caches and servers) configured to store the one or more instructions 624.

An apparatus of the machine 600 may be one or more of a hardware processor 602 (e.g., a central processing unit (CPU), a graphics processing unit (GPU), a hardware processor core, or any combination thereof), a main memory 604 and a static memory 606, sensors 621, network interface device 620, antennas 660, a display device 610, an input device 612, a UI navigation device 614, a mass storage 616, instructions 624, a signal generation device 618, and an output controller 628. The apparatus may be configured to perform one or more of the methods and/or operations disclosed herein. The apparatus may be intended as a component of the machine 600 to perform one or more of the methods and/or operations disclosed herein, and/or to perform a portion of one or more of the methods and/or operations disclosed herein. In some embodiments, the apparatus may include a pin or other means to receive power. In some embodiments, the apparatus may include power conditioning hardware.

The term “machine readable medium” may include any medium that is capable of storing, encoding, or carrying instructions for execution by the machine 600 and that cause the machine 600 to perform any one or more of the techniques of the present disclosure, or that is capable of storing, encoding or carrying data structures used by or associated with such instructions. Non-limiting machine readable medium examples may include solid-state memories, and optical and magnetic media. Specific examples of machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine readable media may include non-transitory machine-readable media. In some examples, machine readable media may include machine readable media that is not a transitory propagating signal.

The instructions 624 may further be transmitted or received over a communications network 626 using a transmission medium via the network interface device 620 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 620 may include one or more physical jacks (e.g., Ethernet, coaxial, or phone jacks) or one or more antennas to connect to the communications network 626. In an example, the network interface device 620 may include one or more antennas 660 to wirelessly communicate using at least one of single-input multiple-output (SIMO), multiple-input multiple-output (MIMO), or multiple-input single-output (MISO) techniques. In some examples, the network interface device 620 may wirelessly communicate using Multiple User MIMO techniques. The term “transmission medium” shall be taken to include any intangible medium that is capable of storing, encoding or carrying instructions for execution by the machine 600, and includes digital or analog communications signals or other intangible medium to facilitate communication of such software.

Examples, as described herein, may include, or may operate on, logic or a number of components, modules, or mechanisms. Modules are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read only memory (ROM); random access memory (RAM); magnetic disk storage media; optical storage media; flash memory, etc.

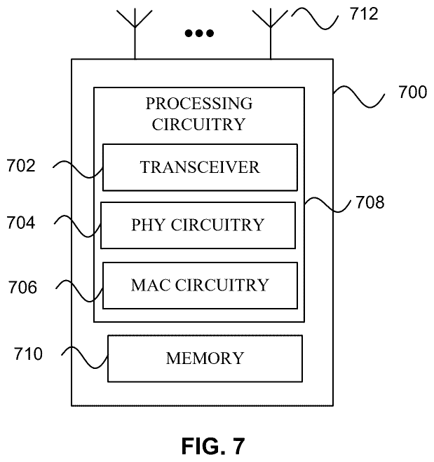

FIG. 7 illustrates a block diagram of an example wireless device 700 upon which any one or more of the techniques (e.g., methodologies or operations) discussed herein may perform. The wireless device 700 may be a HE device or HE wireless device. The wireless device 700 may be a HE STA 504, HE AP 502, and/or a HE STA or HE AP. A HE STA 504, HE AP 502, and/or a HE AP or HE STA may include some or all of the components shown in FIGS. 1-7. The wireless device 700 may be an example machine 600 as disclosed in conjunction with FIG. 6.

The wireless device 700 may include processing circuitry 708. The processing circuitry 708 may include a transceiver 702, physical layer circuitry (PHY circuitry) 704, and MAC layer circuitry (MAC circuitry) 706, one or more of which may enable transmission and reception of signals to and from other wireless devices 700 (e.g., HE AP 502, HE STA 504, and/or legacy devices 506) using one or more antennas 712. As an example, the PHY circuitry 704 may perform various encoding and decoding functions that may include formation of baseband signals for transmission and decoding of received signals. As another example, the transceiver 702 may perform various transmission and reception functions such as conversion of signals between a baseband range and a Radio Frequency (RF) range.

Accordingly, the PHY circuitry 704 and the transceiver 702 may be separate components or may be part of a combined component, e.g., processing circuitry 708. In addition, some of the described functionality related to transmission and reception of signals may be performed by a combination that may include one, any or all of the PHY circuitry 704 the transceiver 702, MAC circuitry 706, memory 710, and other components or layers. The MAC circuitry 706 may control access to the wireless medium. The wireless device 700 may also include memory 710 arranged to perform the operations described herein, e.g., some of the operations described herein may be performed by instructions stored in the memory 710.

The antennas 712 (some embodiments may include only one antenna) may comprise one or more directional or omnidirectional antennas, including, for example, dipole antennas, monopole antennas, patch antennas, loop antennas, microstrip antennas or other types of antennas suitable for transmission of RF signals. In some multiple-input multiple-output (MIMO) embodiments, the antennas 712 may be effectively separated to take advantage of spatial diversity and the different channel characteristics that may result.

One or more of the memory 710, the transceiver 702, the PHY circuitry 704, the MAC circuitry 706, the antennas 712, and/or the processing circuitry 708 may be coupled with one another. Moreover, although memory 710, the transceiver 702, the PHY circuitry 704, the MAC circuitry 706, the antennas 712 are illustrated as separate components, one or more of memory 710, the transceiver 702, the PHY circuitry 704, the MAC circuitry 706, the antennas 712 may be integrated in an electronic package or chip.

In some embodiments, the wireless device 700 may be a mobile device as described in conjunction with FIG. 6. In some embodiments the wireless device 700 may be configured to operate in accordance with one or more wireless communication standards as described herein (e.g., as described in conjunction with FIGS. 1-6, IEEE 802.11). In some embodiments, the wireless device 700 may include one or more of the components as described in conjunction with FIG. 6 (e.g., display device 610, input device 612, etc.) Although the wireless device 700 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, field-programmable gate arrays (FPGAs), application specific integrated circuits (ASICs), radio-frequency integrated circuits (RFICs) and combinations of various hardware and logic circuitry for performing at least the functions described herein. In some embodiments, the functional elements may refer to one or more processes operating on one or more processing elements.

In some embodiments, an apparatus of or used by the wireless device 700 may include various components of the wireless device 700 as shown in FIG. 7 and/or components from FIGS. 1-6. Accordingly, techniques and operations described herein that refer to the wireless device 700 may be applicable to an apparatus for a wireless device 700 (e.g., HE AP 502 and/or HE STA 504), in some embodiments. In some embodiments, the wireless device 700 is configured to decode and/or encode signals, packets, and/or frames as described herein, e.g., PPDUs.

In some embodiments, the MAC circuitry 706 may be arranged to contend for a wireless medium during a contention period to receive control of the medium for a HE TXOP and encode or decode an HE PPDU. In some embodiments, the MAC circuitry 706 may be arranged to contend for the wireless medium based on channel contention settings, a transmitting power level, and a clear channel assessment level (e.g., an energy detect level).

The PHY circuitry 704 may be arranged to transmit signals in accordance with one or more communication standards described herein. For example, the PHY circuitry 704 may be configured to transmit a HE PPDU. The PHY circuitry 704 may include circuitry for modulation/demodulation, upconversion/downconversion, filtering, amplification, etc. In some embodiments, the processing circuitry 708 may include one or more processors. The processing circuitry 708 may be configured to perform functions based on instructions being stored in a RAM or ROM, or based on special purpose circuitry. The processing circuitry 708 may include a processor such as a general purpose processor or special purpose processor. The processing circuitry 708 may implement one or more functions associated with antennas 712, the transceiver 702, the PHY circuitry 704, the MAC circuitry 706, and/or the memory 710. In some embodiments, the processing circuitry 708 may be configured to perform one or more of the functions/operations and/or methods described herein.

In mmWave technology, communication between a station (e.g., the HE STAs 504 of FIG. 5 or wireless device 700) and an access point (e.g., the HE AP 502 of FIG. 5 or wireless device 700) may use associated effective wireless channels that are highly directionally dependent. To accommodate the directionality, beamforming techniques may be utilized to radiate energy in a certain direction with certain beamwidth to communicate between two devices. The directed propagation concentrates transmitted energy toward a target device in order to compensate for significant energy loss in the channel between the two communicating devices. Using directed transmission may extend the range of the millimeter-wave communication versus utilizing the same transmitted energy in omni-directional propagation.

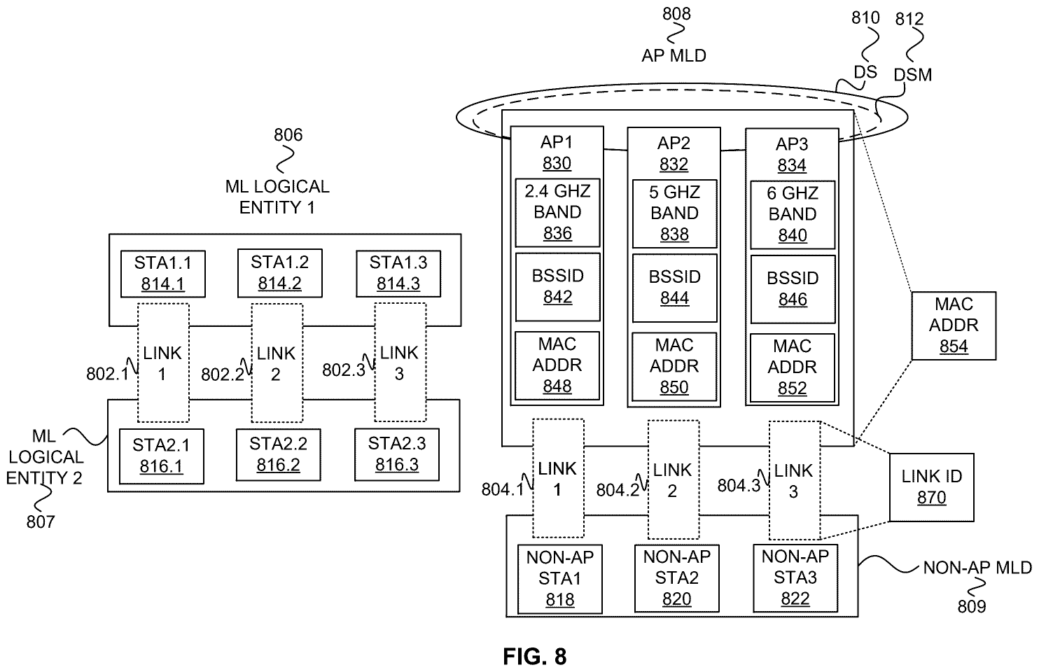

FIG. 8 illustrates multi-link devices (MLD) s 800, in accordance with some embodiments. Illustrated in FIG. 8 is ML logical entity 1 806, ML logical entity 2 807, AP MLD 808, and non-AP MLD 809. The ML logical entity 1 806 includes three STAs, STA1.1 814.1, STA1.2 814.2, and STA1.3 814.3 that operate in accordance with link 1 802.1, link 2 802.2, and link 3 802.3, respectively.

The Links are different frequency bands such as 2.4 GHz band, 5 GHz band, 6 GHz band, and so forth. ML logical entity 2 807 includes STA2.1 816.1, STA2.2 816.2, and STA2.3 816.3 that operate in accordance with link 1 802.1, link 2 802.2, and link 3 802.3, respectively. In some embodiments ML logical entity 1 806 and ML logical entity 2 807 operate in accordance with a mesh network. Using three links enables the ML logical entity 1 806 and ML logical entity 2 807 to operate using a greater bandwidth and more reliably as they can switch to using a different link if there is interference or if one link is superior due to operating conditions.

The distribution system (DS) 810 indicates how communications are distributed and the DS medium (DSM) 812 indicates the medium that is used for the DS 810, which in this case is the wireless spectrum.

AP MLD 808 includes AP1 830, AP2 832, and AP3 834 operating on link 1 804.1, link 2 804.2, and link 3 804.3, respectively. AP MLD 808 includes a MAC ADDR 854 that may be used by applications to transmit and receive data across one or more of AP1 830, AP2 832, and AP3 834. Each link may have an associated link ID. For example, as illustrated, link 3 804.3 has a link ID 870.

AP1 830, AP2 832, and AP3 834 includes a frequency band, which are 2.4 GHz band 836, 5 GHz band 838, and 6 GHz band 840, respectively. AP1 830, AP2 832, and AP3 834 includes different BSSIDs, which are BSSID 842, BSSID 844, and BSSID 846, respectively. AP1 830, AP2 832, and AP3 834 includes different media access control (MAC) address (addr), which are MAC adder 848, MAC addr 850, and MAC addr 852, respectively. The AP 502 is a AP MLD 808, in accordance with some embodiments. The STA 504 is a non-AP MLD 809, in accordance with some embodiments.

The non-AP MLD 809 includes non-AP STA1 818, non-AP STA2 820, and non-AP STA3 822. Each of the non-AP STAs may have MAC addresses and the non-AP MLD 809 may have a MAC address that is different and used by application programs where the data traffic is split up among non-AP STA1 818, non-AP STA2 820, and non-AP STA3 822.

The STA 504 is a non-AP STA1 818, non-AP STA2 820, or non-AP STA3 822, in accordance with some embodiments. The non-AP STA1 818, non-AP STA2 820, and non-AP STA3 822 may operate as if they are associated with a BSS of AP1 830, AP2 832, or AP3 834, respectively, over link 1 804.1, link 2 804.2, and link 3 804.3, respectively.

A multi-link device such as ML logical entity 1 806 or ML logical entity 2 807, is a logical entity that contains one or more STAs 814, 816. The ML logical entity 1 806 and ML logical entity 2 807 each has one MAC data service interface and primitives to the logical link control (LLC) and a single address associated with the interface, which can be used to communicate on the DSM 812. Multi-link logical entity allows STAs 814, 816 within the multi-link logical entity to have the same MAC address. In some embodiments a same MAC address is used for application layers and a different MAC address is used per link.

In infrastructure framework, AP MLD 808, includes AP1 830, AP2 832, and AP3 834, on one side, and non-AP MLD 809, which includes non-AP STA 818, non-AP STA 820, and non-AP STA 822 on the other side.

ML AP device (AP MLD): is a ML logical entity, where each STA within the multi-link logical entity is an EHT AP 502, in accordance with some embodiments. ML non-AP device (non-AP MLD) A multi-link logical entity, where each STA within the multi-link logical entity is a non-AP EHT STA 504. AP1 830, AP2 832, and AP3 834 may be operating on different bands and there may be fewer or more APs. There may be fewer or more STAs as part of the non-AP MLD 809.

In some embodiments the AP MLD 808 is termed an AP MLD or MLD. In some embodiments non-AP MLD 809 is termed a MLD or a non-AP MLD. Each AP (e.g., AP1 830, AP2 832, and AP3 834) of the MLD sends a beacon frame that includes: a description of its capabilities, operation elements, a basic description of the other AP of the same MLD that are collocated, which may be a report in a Reduced Neighbor Report element or another element such as a basic multi-link element. AP1 830, AP2 832, and AP3 834 transmitting information about the other APs in beacons and probe response frames enables STAs of non-AP MLDs to discover the APs of the AP MLD.

In some embodiments, unequal Modulation and Coding Scheme (MCS) (UMCS) and finer MCSs enable the wireless device to use the wireless medium more efficiently. In UMCS, different MCSs are assigned, which may be adaptively, to different spatial streams and different frequency resource blocks (FRBs), resource units (RUs), or multiple RUs (MRUs) with significant signal-to-interference-plus-noise ratio (SINR) imbalance. For spatial streams (SS), this SINR imbalance is caused by the beamforming gain differences across spatial streams. One reason for the SINR imbalance across frequencies is the different interference levels and sensitivities on primary and secondary channels. A resource unit (RU) or a multiple resource unit (MRU) assigned to a user may have different SINR conditions on different FRB, when a RU/MRU is across primary channel and secondary channels with different Clear Channel Assessment (CCA) methods, preamble detect CCA or energy detect CCA.

UMCSs for different spatial streams and FRBs with different SINRs can effectively enhance the data rate and throughput of the wireless medium. On the other hand, in the current Extremely High Throughput (EHT) Physical Layer (PHY) specifications, 14 types of MCSs are defined, which can be selected for wireless transmissions. However, there are totally 28 possible combinations of MCSs. Finer MCS means to define and use more MCS options for data transmissions, which can make selected MCSs more accurate and adapt to wireless environments/SNR conditions better, which may result in higher throughput. However, the EHT-SIG field and the trigger frame in the current EHT specifications, which are utilized to carry MCS information in Physical Layer (PHY) layer and Medium Access Control (MAC) Layer, respectively, can only support Equal MCS and limited MCSs with 14 MCS options. A technical problem is how to signal the UMCS and the finer MCSs. The technical problem is addressed with the embodiments disclosed herein. The finer MCS options may require more bits to signal the MCS information. In some embodiments, a modulation gap between UMCSs may be used to restrict the MCS options. For example, the modulation gap between two unequal MCSs may be less than or equal to 2 modulation orders. In some embodiments, signal (SIG) fields and trigger frames enable UMCSs and finer MCSs in both the PHY layer and the MAC layer. In some embodiments, for finer MCSs, more bits are assigned to signaling the MCS information to cover indexes for more MCS options. In some embodiments, for UMCS, a restriction is used that the modulation gap between UMCSs is limited, which may reduce the number of signaling bits needed. Additionally, another technical problem is how to signal additional MCSs, UEQM for different RUs, MRUs, FRUs, and/or SSs, as well as 2×LDPC.

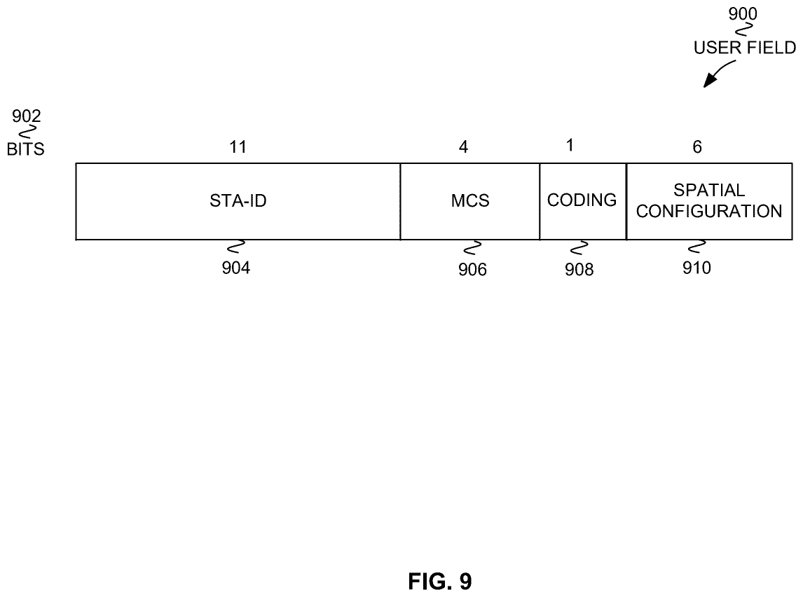

Table 1 illustrates an EHT-MCSs table, including Modulation and Coding Scheme (MCS) options and indexes for Extremely High Throughput (EHT) Physical Layer (PHY) signaling, where there are 15 types of MCSs. With 15 MCS options, 4 bits are used to indicate all indexes of 15 MCSs in EHT PPDUs. EHT-MCS index 14 is reserved. FIG. 9 illustrates a user field 900 field, in accordance with some embodiments. The user field 900 field is part of a user specific field of an EHT-SIG of EHT/IEEE 802.11be/Wi-Fi 7. The bits 902 indicates the bits of the corresponding field. The MCS 906 field has 4 bits. The station identification (STA-ID) 904 field comprises an identification for the STA. The coding 908 field indicates a type of forward error correcting (FEC) coding used on the packet comprising the user field 900. The spatial configuration 910 indicates an allocation of a spatial streams. The user field 900 field provides MCS information for the PHY layer. In some embodiments, the coding 908 field indicates 1×LPDC or 2×LDDC.

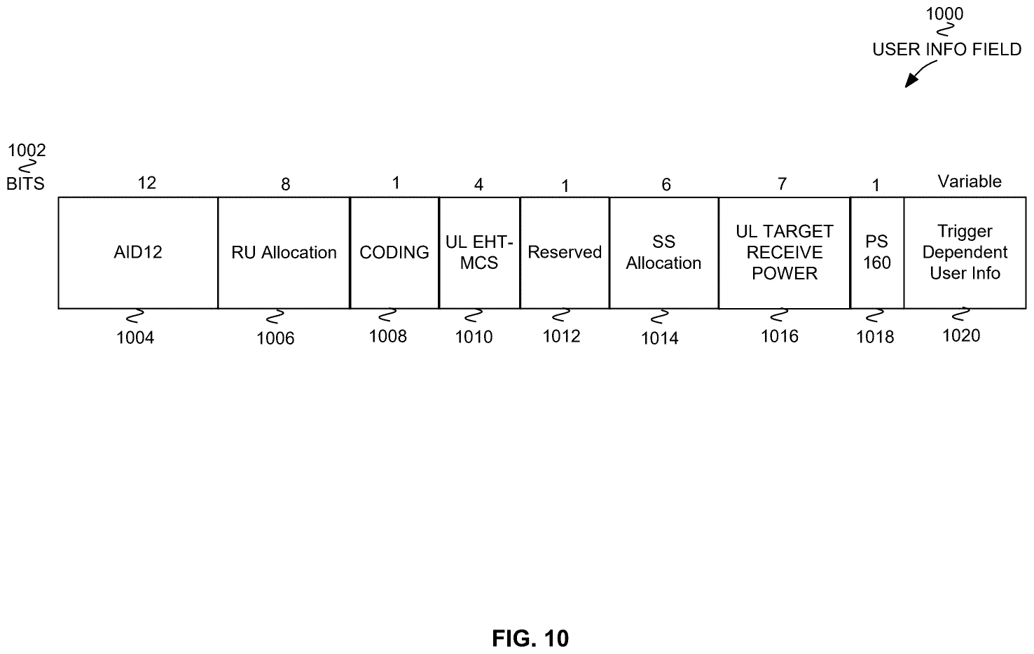

FIG. 10 illustrates a user info field 1000, in accordance with some embodiments. The user info field 1000 is part of the trigger frame of the EHT/IEEE 802.11be/Wi-Fi 7. The uplink user info field 1000 includes an AID12 1004 field, RU allocation 1006 field, a coding 1008 field, an UL EHT-MCS 1010 field, a reserved 1012 field, an SS allocation 1014 field, an UL target receive power 1016 field, a PS 160 field, and a trigger dependent user information (info) 1020 field.

The SS allocation 1014 field includes SS Allocation/RA-RU Information. The coding 1008 field includes an UL FEC Coding Type. The user info field 1000 provides MSC information for the medica access control (MAC) layer. The UL EHT-MCS 1010 field is 4 bits 1002. In some embodiments, the user info field 1000 is part of a user information field of a trigger frame for the user identified by AID12 1004 field. In some embodiments, the coding 1008 field indicates 1×LPDC or 2×LDDC.

Table 1 illustrates the following:

TABLE 1

| EHT-MCS index | Modulation | Coding Rate |
|---|---|---|
| 0 | BPSK | 1/2 |
| 1 | QPSK | 1/2 |
| 2 | | 3/4 |
| 3 | 16-QAM | 1/2 |
| 4 | | 3/4 |
| 5 | 64-QAM | 2/3 |
| 6 | | 3/4 |
| 7 | | 5/6 |
| 8 | 256-QAM | 3/4 |
| 9 | | 5/6 |
| 10 | 1024-QAM | 3/4 |
| 11 | | 5/6 |
| 12 | 4096-QAM | 3/4 |
| 13 | | 5/6 |
| 15 | BPSK-DCM | 1/2 |

Unequal MCSs and Finer MCSs may significantly improve performance and/or reliability. UMCSs require an EHT-SIG in the PHY layer and Trigger Frame signaling in MAC layer to be able to convey the information for the additional MCSs. For Finer MCS, more MCS types are added. In some embodiments, Table 1 of the EHT-MCSs is expanded to include an additional 15 MCSs.

In some embodiments, there are a total of 8 modulations, including BPSK, QPSK, 16-QAM, 64-QAM, 256-QAM, 1024-QAM, and 4094-QAM, and 4 types of Low-Density Parity Check (LDPC) coding rates, which are 1/2, 2/3, 3/4, and 5/6. There are a total of 28 (7×4) types of MCSs with LDPC FEC. In some embodiments, with finer MCSs adds 14 new MCSs to extend UHR-MCSs from 15 types to 29 types of MCS. Table 2 is an example of extending UHR-MCSs from 15 types to 29 types, where indexes from 16 to 29 indicate new added MCS types. In Table 2, new MCSs are listed following behind original EHT-MCSs for compatibility. In this way, the current version of Wi-Fi systems (EHT/802.11be/Wi-Fi 7) can also use the UHR-MCS table with Finer MCS as shown in Table 2, as indexes of original EHT-MCSs remain unchanged. In other words, Wi-Fi 7/EHT systems and Wi-Fi 8/UHR systems can share the same UHR-MCSs table with Finer MCS. In Table 2, there is no index 14, as in Table 1, because index 14 is reserved.

Table 2 illustrates the following:

TABLE 2

| EHT-MCS index | Modulation | Coding Rate |
|---|---|---|
| 0 | BPSK | 1/2 |
| 1 | QPSK | 1/2 |
| 2 | | 3/4 |
| 3 | 16-QAM | 1/2 |
| 4 | | 3/4 |
| 5 | 64-QAM | 2/3 |
| 6 | | 3/4 |
| 7 | | 5/6 |
| 8 | 256-QAM | 3/4 |
| 9 | | 5/6 |
| 10 | 1024-QAM | 3/4 |
| 11 | | 5/6 |
| 12 | 4096-QAM | 3/4 |
| 13 | | 5/6 |
| 15 | BPSK-DCM | 1/2 |
| 16 | BPSK | 2/3 |
| 17 | | 3/4 |
| 18 | | 5/6 |
| 19 | QPSK | 2/3 |
| 20 | | 5/6 |
| 21 | 16-QAM | 2/3 |
| 22 | | 5/6 |
| 23 | 64-QAM | 1/2 |
| 24 | 256-QAM | 1/2 |
| 25 | | 2/3 |
| 26 | 1024-QAM | 1/2 |
| 27 | | 2/3 |
| 28 | 4096-QAM | 1/2 |
| 29 | | 2/3 |

Table 3 illustrates another embodiment of adding MCSs where the new MCSs are inserted into Table 1 and listed in the order of low modulations to high modulations where indexes of 1, 2, 3, 5, 7, 9, 11, 12, 16, 17, 20, 21, 24, and 25, are indexes of new added MCSs. However, the indexes of Table 3 are different than Table 1, so Table 3 is for Wi-Fi 8/UHR/IEEE 802.11bn systems but cannot be used by Wi-Fi 7/EHT/IEEE 802.11be systems. As a result, users of Wi-Fi 7 systems need to follow Table 1 and Wi-Fi 8 systems need to follow Table 3.

Table 3 illustrates the following:

TABLE 3

| EHT-MCS index | Modulation | Coding Rate |
|---|---|---|
| 0 | BPSK | 1/2 |
| 1 | | 2/3 |
| 2 | | 3/4 |
| 3 | | 5/6 |
| 4 | QPSK | 1/2 |
| 5 | | 2/3 |
| 6 | | 3/4 |
| 7 | | 5/6 |
| 8 | 16-QAM | 1/2 |
| 9 | | 2/3 |
| 10 | | 3/4 |
| 11 | | 5/6 |
| 12 | 64-QAM | 1/2 |
| 13 | | 2/3 |
| 14 | | 3/4 |
| 15 | | 5/6 |
| 16 | 256-QAM | 1/2 |
| 17 | | 2/3 |
| 18 | | 3/4 |
| 19 | | 5/6 |
| 20 | 1024-QAM | 1/2 |
| 21 | | 2/3 |
| 22 | | 3/4 |
| 23 | | 5/6 |
| 24 | 4096-QAM | 1/2 |
| 25 | | 2/3 |
| 26 | | 3/4 |
| 27 | | 5/6 |
| 28 | BPSK-DCM | 1/2 |

Note that UHR-MCSs tables with Finer MCS presented in Table 2 and Table 3 include all possible 28 MCS types with 14 new MCSs added. In some embodiments, the number of added MCSs is less than 14 and a subset of 14 new MCSs is added in Finer MCS rather than all 14 possible MCSs. For example, only 6 out of 14 new MCSs are added, so that the total number of Finer UHR-MCSs is 21 rather than 29. With Finer MCS, more bits may be required to indicate all indexes of MCSs. In EHT-MCSs, there are totally 15 types of MCSs, so 4 bits can represent the 15 types. However, with Finer MCS, the number of MCSs can be up to 29, and 5 bits are required to cover indexes of up to 29 MCS types. In some embodiments, the subfield indicating the MCS in the PHY preamble and in the MAC portion of the trigger frame is 5 bits or more bits for UHR/802.11bn.

In UMCS, different MCSs are assigned to different spatial streams or FRBs to adapt to the SINR conditions and SINR imbalances in the different spatial streams or FRBs. In some embodiments, indicating the UMCS requires more than 4 bits to convey the information for multiple MCSs rather than a single MCS. In some embodiments, to reduce the complexity, the UMCSs of an UHR user share the same coding rate (R) and only modulations are different. The characteristics or features of UMCS include the following.

In some embodiments, there is a modulation gap restriction between adjacent FRBs, RU, SSs, or MRUs. The modulation gap (difference between the two modulations used) between two adjacent MCSs assigned to two adjacent spatial streams is restricted. In some embodiments, the spatial streams share the same coding rate. The modulation of a MCS can be lower than that of its previous MCS within a pre-defined certain level. For example, the modulation gap between two adjacent MCSs is restricted to be up to two modulation orders. If the modulation of the first MCS is 1024-QAM, the modulation of the second MCS can only be 1024-QAM, 256-QAM, or 64-QAM, which cannot be more than 2 orders lower than 1024-QAM. This is because in most cases, the gap of up to 2 modulation orders can handle SINR imbalance on two adjacent spatial streams. Modulation gap restriction can greatly reduce the number of possible modulation combinations in UMCS with simpler signaling, lower overhead, and lower complexity.

In some embodiments, pre-defined patterns of UMCS are used. A user may be assigned multiple spatial streams. The UMCS pattern specifies how the modulation orders vary over the spatial streams. For example, a 3-level pattern is applied to a 4-spatial-stream scenario, like QAM-0/QAM-0/QAM-1/QAM-2. This means that the first spatial stream and the second spatial stream share the same modulation order, QAM-0, while the third spatial stream's modulation, QAM-1, is lower than or equal to QAM-0, the modulation of the first spatial stream and the second spatial stream. The fourth spatial stream uses the lowest modulation, QAM-2, which is lower than or equal to QAM-1. The pre-defined pattern of Unequal MCS over spatial streams is based on the characteristics of the SINR imbalance over spatial streams or for other reasons. For example, in 4-spatial-stream scenarios, it is likely for the first spatial stream and the second spatial stream have similar SINR conditions, while a significant SINR drop usually occurs in the third spatial stream and the fourth spatial stream. Thus, the pattern of QAM-0/QAM-0/QAM-1/QAM-2 can be applied to many of the cases. The use of pre-defined patterns of UMCS reduces the number of possible modulation combinations in UMCS for simpler signaling, lower overhead, and lower complexity.

Both the modulation gap restriction and the pre-defined pattern of UMCS reduce possible modulation combinations of UMCS. Without the modulation gap restriction and the pre-defined pattern, the number of possible modulation combinations in UMCS would be very high and require large numbers of bits to indicate the indexes of the UMCS per spatial stream. The modulation gap restriction and the pre-defined patterns, reduce the possible modulation combinations in UMCS, which requires fewer bits to signal or indicate the indexes of the MCS combinations.

The number of bits required to signal the information for the finer MCS and UMCS when the modulation gap restriction and the pre-defined patterns are used is disclosed. In some embodiments, for finer MCS, all possible 28 MCSs are included, consisting of 7 modulations, BPSK, QPSK, 16-QAM, 64-QAM, 256-QAM, 1024-QAM, and 4096-QAM, and 4 types of coding rates, 1/2, 2/3, 3/4, and 5/6. In some embodiments, additional modulations are used and/or additional coding rates are used.

In some embodiments, not all the possible MCSs for finer MCS are included or have an index. In some embodiments, in finer MCS, all 28 MCSs are included (or the number of modulations times the number of coding rates where the number of modulations is 7 or more and the number of coding rates is four or more). The maximum number of bits required to support UMCS and finer MCS for 7 modulations and four coding rates is discussed. For UMCS, it is assumed that the modulation gap restriction between two adjacent MCSs assigned to 2 adjacent spatial streams is up to 2 modulation orders. Scenarios of 2 spatial streams and 4 spatial streams are discussed. The pre-defined pattern of UMCS in two spatial streams scenarios is QAM-0/QAM-1. In scenarios of 4 spatial streams, two types of patterns, QAM-0/QAM-0/QAM-1/QAM-2 and QAM-0/QAM-0/QAM-0/QAM-1, are taken into consideration, where the modulation order of QAM-x is higher than or equal to QAM-y, if x<y.

Table 4 and Table 5 shows modulation combinations of 2 MCSs assigned to 2 spatial streams with no modulation gap restriction for Table 4 and with the modulation gap restriction of up to 2 for Table 5. Without the modulation gap restriction as illustrated in Table 4, the number of modulation combinations is 28, each of which has 4 types of coding rates, for up to 4×28=112 MCS combinations. The 112 MCS combinations requires 7 bits to indicate indexes of all 112 MCS combinations for UMCS with 2 MCSs. Seven (7) bits can provide up to 128 indexes. In Table 5, with the modulation gap restriction of up to 2 modulation orders, the number of modulation combinations is reduced to 18, each of which has 4 types of coding rates. Accordingly, there is 4×18=72 MCS combinations, which requires 7 bits to signal. Although the number of MCS combinations decrease from 112 to 72 by using the modulation gap restriction of up to 2 modulation orders, the number of required bits is still 7 bits.

Table 4 illustrates modulation combinations of 2 MCSs with finer MCSs and UMCS (with no modulation gap restriction and with the pattern of QAM-0/QAM-1).

TABLE 4

| First | | | | | | | | |
|---|---|---|---|---|---|---|---|---|
| MCS's | | | | | | | | Total |
| Modulation | Second MCS's Modulation | | | | | | | Entries |
| BPSK | BPSK | | | | | | | 1 |
| QPSK | QPSK | BPSK | | | | | | 2 |
| 16-QAM | 16-QAM | QPSK | BPSK | | | | | 3 |
| 64-QAM | 64-QAM | 16-QAM | QPSK | BPSK | | | | 4 |
| 256-QAM | 256-QAM | 64-QAM | 16-QAM | QPSK | BPSK | | | 5 |
| 1024-QAM | 1024-QAM | 256-QAM | 64-QAM | 16-QAM | QPSK | BPSK | | 6 |
| 4096-QAM | 4096-QAM | 1024-QAM | 256-QAM | 64-QAM | 16-QAM | QPSK | BPSK | 7 |

Table 5 illustrates modulation combinations of 2 MCSs with finer MCSs and UMCS (for a modulation gap restriction of up to 2 modulation orders and the pattern of QAM-0/QAM-1).

TABLE 5

| First MCS's | | | | Total |
|---|---|---|---|---|
| Modulation | Second MCS's Modulation | | | Entries |
| BPSK | BPSK | | | 1 |
| QPSK | QPSK | BPSK | | 2 |
| 16-QAM | 16-QAM | QPSK | BPSK | 3 |
| 64-QAM | 64-QAM | 16-QAM | QPSK | 3 |
| 256-QAM | 256-QAM | 64-QAM | 16-QAM | 3 |
| 1024-QAM | 1024-QAM | 256-QAM | 64-QAM | 3 |
| 4096-QAM | 4096-QAM | 1024-QAM | 256-QAM | 3 |

Table 6 illustrates the case of 4 MCSs assigned to 4 spatial streams, and modulation combinations of the pattern of QAM-0/QAM-0/QAM-1/QAM-2 with no modulation gap restriction and Table 7 illustrates the same case but with the modulation gap restriction of up to 2 modulation orders. In Table 6, the pattern of QAM-0/QAM-0/QAM-1/QAM-2 with no modulation gap restriction has 84 modulation combinations, each of which has 4 MCSs, and along with 4 types of coding rates totally 4×84=336 MCS combinations, which require 9 bits to indicate the indexes. For the pattern of QAM-0/QAM-0/QAM-1/QAM-2 with the modulation gap restriction of up to 2 modulation orders shown in Table 7, 45 modulation combinations combined with 4 types of coding rates result in totally 180 MCS combinations, requiring 8 bits to indicate the indexes. In finer MCS and UMCS with 4 MCSs and the pattern of QAM-0/QAM-0/QAM-1/QAM-2, utilizing the modulation gap restriction of up to 2 modulation orders can decrease the number of MCS combinations from 336 to 180. As a result, 1 bit is saved with required bits reduced from 9 bits to 8 bits. Table 8 shows the modulation combinations of another easier pattern, QAM-0/QAM-0/QAM-0/QAM-1, with the modulation gap restriction of up to 2 modulation orders. This easier pattern can make the number of modulation combinations reduced to only 18 modulation combinations. Along with 4 coding rates, there are 4×18=72 MCS combinations in total, which requires 7 bits to indicate the different 72 MCS combinations.

In some embodiments, the UEQM pattern, which may be indicated by a UEQM pattern subfield or another subfield, indicates a relative reduction of the modulation order with respect to the modulation order of the first spatial stream. For each pattern, the QAM orders are arranged in a descending order. For each number of spatial streams, a fixed number of patterns is defined. The number of patterns is not greater than 4. The number of indication bits is two. In some embodiments, the UEQM pattern is pre-defined patterns for 4 spatial streams and comprises QAM/QAM/QAM-1/QAM-2 and QAM/QAM/QAM/QAM-1. The pre-defined patterns for 2 spatial streams comprises QAM/QAM-1. In some embodiments, the MCS subfield indicates the highest modulation order of the all the spatial streams and the common code rate of all the streams. In some embodiments, the UEQM pattern includes the QAM order reduction that is between two adjacent spatial streams and is limited to 0 or 1. A UHR PPDU comprises a common field and user specific fields. The user specific field includes subfields. The user specific fields may be termed user fields, UHR user fields, UHR user info fields, user info fields, or another term. The PPDUs may be termed UHR non-MU MIMO PPDUs, UHR MU MIMO PPDUs where the UHR may be optional.

Table 6 illustrates modulation combinations of 4 MCSs with finer MCSs and UMCS (with no modulation gap restriction and the restriction pattern of QAM-0/QAM-0/QAM-1/QAM-2).

TABLE 6

| First | Second | Third | Fourth | |
|---|---|---|---|---|
| MCS's | MCS's | MCS's | MCS's | Total |
| modulation | modulation | modulation | modulation | Entries |
| BPSK | BPSK | BPSK | BPSK | 1 |
| QPSK | QPSK | QPSK | QPSK/BPSK | 2 |
| QPSK | QPSK | BPSK | BPSK | 1 |
| 16-QAM | 16-QAM | 16-QAM | 16- | 3 |
| | | | QAM/QPSK/BPSK | |
| 16-QAM | 16-QAM | QPSK | QPSK/BPSK | 2 |
| 16-QAM | 16-QAM | BPSK | BPSK | 1 |
| 64-QAM | 64-QAM | 64-QAM | 64-QAM/16- | 4 |
| | | | QAM/QPSK/BPSK | |
| 64-QAM | 64-QAM | 16-QAM | 16- | 3 |
| | | | QAM/QPSK/BPSK | |
| 64-QAM | 64-QAM | QPSK | QPSK/BPSK | 2 |
| 64-QAM | 64-QAM | BPSK | BPSK | 1 |
| 256-QAM | 256-QAM | 256-QAM | 256-QAM/64- | 5 |
| | | | QAM/16- | |
| | | | QAM/QPSK/BPSK | |
| 256-QAM | 256-QAM | 64-QAM | 64-QAM/16- | 4 |
| | | | QAM/QPSK/BPSK | |
| 256-QAM | 256-QAM | 16-QAM | 16- | 3 |
| | | | QAM/QPSK/BPSK | |
| 256-QAM | 256-QAM | QPSK | QPSK/BPSK | 2 |
| 256-QAM | 256-QAM | BPSK | BPSK | 1 |
| 1024-QAM | 1024-QAM | 1024-QAM | 1024-QAM/256- | 6 |
| | | | QAM/64-QAM/16- | |
| | | | QAM/QPSK/BPSK | |
| 1024-QAM | 1024-QAM | 256-QAM | 256-QAM/64- | 5 |
| | | | QAM/16- | |
| | | | QAM/QPSK/BPSK | |
| 1024-QAM | 1024-QAM | 64-QAM | 64-QAM/16- | 4 |
| | | | QAM/QPSK/BPSK | |
| 1024-QAM | 1024-QAM | 16-QAM | 16- | 3 |
| | | | QAM/QPSK/BPSK | |
| 1024-QAM | 1024-QAM | QPSK | QPSK/BPSK | 2 |
| 1024-QAM | 1024-QAM | BPSK | BPSK | 1 |
| 4096-QAM | 4096-QAM | 4096-QAM | 4096-QAM/1024- | 7 |
| | | | QAM/256- | |
| | | | QAM/64-QAM/16- | |
| | | | QAM/QPSK/BPSK | |
| 4096-QAM | 4096-QAM | 1024-QAM | 1024-QAM/256- | 6 |
| | | | QAM/64-QAM/16- | |
| | | | QAM/QPSK/BPSK | |
| 4096-QAM | 4096-QAM | 256-QAM | 256-QAM/64- | 5 |
| | | | QAM/16- | |
| | | | QAM/QPSK/BPSK | |
| 4096-QAM | 4096-QAM | 64-QAM | 64-QAM/16- | 4 |
| | | | QAM/QPSK/BPSK | |
| 4096-QAM | 4096-QAM | 16-QAM | 16- | 3 |
| | | | QAM/QPSK/BPSK | |
| 4096-QAM | 4096-QAM | QPSK | QPSK/BPSK | 2 |
| 4096-QAM | 4096-QAM | BPSK | BPSK | 1 |

Table 7 illustrates modulation combinations of 4 MCSs with finer MCS and UMCS (with the modulation gap restriction of up to 2 modulation orders and with the pattern of QAM-0/QAM-0/QAM-1/QAM-2)

TABLE 7

| First | Second | Third | Fourth | |
|---|---|---|---|---|
| MCS's | MCS's | MCS's | MCS's | Total |
| modulation | modulation | modulation | modulation | Entries |
| BPSK | BPSK | BPSK | BPSK | 1 |
| QPSK | QPSK | QPSK | QPSK/BPSK | 2 |
| QPSK | QPSK | BPSK | BPSK | 1 |
| 16-QAM | 16-QAM | 16-QAM | 16- | 3 |
| | | | QAM/QPSK/BPSK | |
| 16-QAM | 16-QAM | QPSK | QPSK/BPSK | 2 |
| 16-QAM | 16-QAM | BPSK | BPSK | 1 |
| 64-QAM | 64-QAM | 64-QAM | 64-QAM/16- | 3 |
| | | | QAM/QPSK | |
| 64-QAM | 64-QAM | 16-QAM | 16- | 3 |
| | | | QAM/QPSK/BPSK | |
| 64-QAM | 64-QAM | QPSK | QPSK/BPSK | 2 |
| 256-QAM | 256-QAM | 256-QAM | 256-QAM/64- | 3 |
| | | | QAM/16-QAM | |
| 256-QAM | 256-QAM | 64-QAM | 64-QAM/16- | 3 |
| | | | QAM/QPSK | |
| 256-QAM | 256-QAM | 16-QAM | 16- | 3 |
| | | | QAM/QPSK/BPSK | |
| 1024-QAM | 1024-QAM | 1024-QAM | 1024-QAM/256- | 3 |
| | | | QAM/64-QAM | |
| 1024-QAM | 1024-QAM | 256-QAM | 256-QAM/64- | 3 |
| | | | QAM/16-QAM | |
| 1024-QAM | 1024-QAM | 64-QAM | 64-QAM/16- | 3 |
| | | | QAM/QPSK | |
| 4096-QAM | 4096-QAM | 4096-QAM | 4096-QAM/1024- | 3 |
| | | | QAM/256-QAM | |
| 4096-QAM | 4096-QAM | 1024-QAM | 1024-QAM/256- | 3 |
| | | | QAM/64-QAM | |
| 4096-QAM | 4096-QAM | 256-QAM | 256-QAM/64- | 3 |
| | | | QAM/16-QAM | |

Table 8 illustrates modulation combinations of 4 MCSs with finer MCS and UMCS (with the modulation gap restriction of up to 2 modulation orders and the pattern of QAM-0/QAM-0/QAM-0/QAM-1)

TABLE 8

| First | Second | Third | Fourth | |
|---|---|---|---|---|
| MCS's | MCS's | MCS's | MCS's | Total |
| modulation | modulation | modulation | modulation | Entries |
| BPSK | BPSK | BPSK | BPSK | 1 |
| QPSK | QPSK | QPSK | QPSK/BPSK | 2 |
| 16-QAM | 16-QAM | 16-QAM | 16- | 3 |
| | | | QAM/QPSK/BPSK | |
| 64-QAM | 64-QAM | 64-QAM | 64-QAM/16- | 3 |
| | | | QAM/QPSK | |
| 256-QAM | 256-QAM | 256-QAM | 256-QAM/64- | 3 |
| | | | QAM/16-QAM | |
| 1024-QAM | 1024-QAM | 1024-QAM | 1024-QAM/256- | 3 |
| | | | QAM/64-QAM | |
| 4096-QAM | 4096-QAM | 4096-QAM | 4096-QAM/1024- | 3 |
| | | | QAM/256-QAM | |

Table 9 summarizes the required bits for different UMCS types. Table 9 illustrates that using the modulation gap restriction can reduce the required bits to indicate the information for UMCS and finer MCS, when the number of MCSs and spatial streams becomes large, for example 4 MCSs assigned to 4 spatial streams. Moreover, the pre-defined pattern of UMCS can further reduce the required bits. For example, QAM-0/QAM-0/QAM-0/QAM-1 is an easier pre-defined pattern for UMCS compared with QAM-0/QAM-0/QAM-1/QAM-2.

Table 9 illustrates the number of required bits to indicate different UMCS types with finer MCSs.

TABLE 9

| | | | 4 MCSs (4 spatial streams) | | |
|---|---|---|---|---|---|
| | 2 MCSs (2 spatial streams) | | QAM-0/QAM-0/ | | QAM-0/QAM-0/ |
| | QAM-0/QAM-1 | | QAM-1/QAM-2 | | QAM-0/QAM-1 |
| | | Modulation gap | | Modulation gap | Modulation gap |
| | No | restriction | No | restriction | restriction |
| | modulation | of up to 2 | modulation | of up to 2 | of up to 2 |
| Unequal | gap | modulation | gap | modulation | modulation |
| MCS types | restriction | orders | restriction | orders | orders |
| Number of | 112 | 72 | 336 | 180 | 72 |
| MCS | | | | | |
| combinations | | | | | |
| Required bits | 7 | 7 | 9 | 8 | 7 |

When UMCS and finer MCS are used, a user is aware of its spatial stream allocations information, including which and how many spatial streams are allocated to it. For downlink (DL) transmissions in the PHY layer, this information is provided by the spatial configuration 910 field of the user field 900 of the user specific field of the user field 900 in the EHT/Wi-Fi 7/IEEE 802.11 communication specification. In some embodiments, this information is indicated in the User field of the UHR-SIG that is the signal field of UHR.

For Uplink (UL) transmissions in the MAC layer, the information of spatial streams allocations is carried by the SS Allocation 1014 field (SS allocation RA-RU Information subfield) of the user info field 1000 in the Trigger Frame in the EHT/Wi-Fi 7/IEEE 802.11be MAC specifications. In some embodiments, this information is indicated in an SS allocation field of a trigger frame in UHR/Wi-Fi 8/IEEE 802.11bn. In some embodiments, spatial streams allocations information, UMCS and finer MCS with the different number of MCSs and spatial streams share the same set of bits to indicate their MCS combinations.

In some embodiments, Joint Indication is used. For each number of spatial streams, a group of the MCS combinations can be selected. The selected MCS combinations of the group can be indexed such that the index can be signaled in one or more fields. The MCSs of the spatial streams are jointly indicated. Table 10 illustrates an example of the UHR-MCS/UL UHR-MCS subfield encoding for UMCS and finer MCS, where a user can be assigned with 2 or 4 MCSs/spatial streams. The embodiment of 2 MCSs/spatial streams and 4 MCSs/spatial streams can reuse the same set of 8 bits to indicate their MCS combinations. The embodiment of 2 MCSs use 8 bits of 00000000 to 01000111 to indicate indexes of 72 MCS combinations, while the scenario of 4 MCSs uses 8 bits of 00000000 to 10110011 to indicate indexes of its 180 MCS combinations. After a user knows its spatial streams allocations and bits included in its UHR-MCS/UL UHR-MCS subfield, the user decodes a MCS combination based on the number of spatial streams assigned and bits received in the UHR-MCS/UL UHR-MCS subfield.

Table 10 illustrates UHR-MCS/UL UHR-MCS subfield encoding.

TABLE 10

| | | Number of |
|---|---|---|
| Number of spatial | | MCS |
| streams | B7 . . . B0 | combinations |
| 2 | 00000000- | 72 |
| (Modulation gap | 01000111 | |
| restriction) | | |
| 4 | 00000000- | 180 |
| (Modulation gap | 10110011 | |
| restriction and | | |
| QAM-0/QAM-0/ | | |
| QAM-1/QAM-2) | | |

In some embodiments, a modulation decrease pattern is used. For each number of spatial streams, a group of the MCS combinations can be selected. The selected MCS combinations of the group can be indexed such that the index can be signaled in the UHR-MCS/UL field, UHR-MCS field, or another field. In some embodiments, the MCS of the first spatial stream can be indicated using 4 or 5 bits. In the case of 5 bits, both the conventional MCSs and the added finer MCSs can be indicated. The indication of the first MCS indicates both the modulation order of the first spatial stream and the code rate for all spatial streams. For each of the first MCSs and each number of spatial streams, a group of modulation order combinations for the other spatial streams can be selected. The spatial streams are sorted and indexed in a decreasing order of the channel qualities. Therefore, the modulation orders of the spatial streams are also in non-increasing orders. This helps to reduce the number of MCS indication bits. The selected modulation order combinations of the group are indexed by 2-3 bits. The number of spatial streams and the first stream MCS narrows down the range of the operating SINR of the current transmission such that the choices for the modulation orders of the remaining spatial streams are limited. Utilizing the modulation gap restriction, the choices are further reduced such that 2 (or more) indication bits are used. Because of the limited choices, the indication bits of the modulation orders are reduced.

The following example illustrates the encoding. In this example, the equal MCS is also included as the first entry of the combination Table 12 and Table 13. In the example, the number of spatial streams is 4. Table 11 illustrates the MCS bits. In the example, the MCS of the first spatial stream is 1024QAM (indicated by bits B0-B4 of Table 11) with a code rate 3/4 (indicated by B5 and B6 of Table 11). The MCS of the first spatial stream is indicated by the first 5 bits of a MCS subfield. The code rate of the remaining 3 streams is also 3/4. The modulation order combination of the remaining 3 spatial streams is selected from Table 12 or Table 13 using the last 2 bits of the MCS subfield of Table 11. Table 12 and Table 13 are similar or equivalent. Table 12 spells out the exact modulation orders. And Table 13 specifies the relative decrease of the modulation order with respect to the previous spatial stream.

Table 11 illustrates an example of the MCS bits.

TABLE 11

| MCS indication | |
|---|---|
| bits | Comments |
| B0-B4 | MCS of the first spatial stream indicating both |
| | modulation order and code rate |
| B5-B6 | Modulation orders for the remaining spatial streams |

Table 12 illustrates a table of modulation order combinations.

| Index of | | | |
|---|---|---|---|
| Modulation | Modulation | Modulation | Modulation |
| Order | of spatial | of spatial | of spatial |
| Combination | stream 2 | stream 3 | stream 4 |
| 0 | 1024QAM | 1024QAM | 1024QAM |
| 1 | 1024QAM | 256QAM | 64QPSK |
| 2 | 256QAM | 64QAM | 16QAM |
| 3 | 256QAM | 16QAM | BPSK |

Table 13 illustrates a table of modulation decrease patterns.

| | Modulation | Modulation | Modulation |
|---|---|---|---|
| | order decrease | order decrease | order decrease |
| Index of | for spatial | for spatial | for spatial |
| Modulation | stream 2 with | stream 3 with | stream 4 with |
| Order | respect to | respect to | respect to |
| Combination | spatial stream 1 | spatial stream 2 | stream 3 |
| 0 | 0 | 0 | 0 |
| 1 | 0 | 1 | 1 |
| 2 | 1 | 1 | 1 |
| 3 | 1 | 2 | 2 |

In some embodiments, defining one table or set for each first MCS and each spatial stream number increases the performance for a given indication overhead. For different SNR regions, the better table or set should be different. For example, for medium SNRs, the modulation orders of the first and the second streams tend to be different due to the channel quality difference of the beamformed channels. However, for high SNR, the modulation orders of the first and second streams tend to be equal because the modulation order of the first stream may be already saturated at the highest modulation order like 4096QAM such that the first modulation order can be higher than the second one.

In the example above of Tables 11-13, because the specification needs to define one order combination table per first MCS per stream number, there are about 50 tables. For reducing the table number at the cost of slightly more MCS indication bits or slight performance loss, the first MCSs share the same modulation order may share the same order combination table such that the number of tables is reduced by about four. In some embodiments, for reducing the table number at the cost of slightly more MCS indication bits or slight performance loss, the first MCSs share the same code rate may share the same order combination table such that the number of tables is reduced by about seven times. In this option, the table of modulation order combinations like Table 12 needs to include the modulation order of the first spatial stream and the code rate of all streams is indicated by 2 (or 3) bits. Table 13 is used for this alternative because it specifies the relative decrease of modulation order. In some embodiments, one decrease pattern table (or set) of modulation order is defined for each number of spatial streams. All first MCSs share the same decrease pattern table for each given number of spatial streams. In this case, only three decrease pattern tables like the one of Table 13 are needed for 2, 3, and 4 spatial streams.

In some embodiments, the encoding of the information is applied to UMCS across spatial streams and UMCS across FRBs, RUs, or component RUs of an MRU assigned to a user. Even using the modulation gap restriction and the pre-defined pattern of UMCS to reduce bit cost in supporting UMCS and finer MCS, more than 4 bits are used. In some embodiments, the MCS subfield of the user field of the User Specific Field in EHT-SIG in the current EHT PHY specifications and UL EHT-MCS subfield of the User Info Field in Trigger Frame in the current EHT MAC specifications provide only 4 bits. Thus, more bits are used to enable UMCS and finer MCS.

In some embodiments, the additional bits that could be used for indicating UMCS and finer MCS are as follows.

Spatial Configuration subfield/SS Allocation/RA-RU Information subfield: 6 bits are included in the Spatial Configuration subfield of EHT-SIG in PHY layer and in the SS Allocation/RA-RU Information subfield of Trigger Frame in MAC layer. However, the original design of them is based on up to 16 spatial streams. In practice, the number of spatial streams is up to 8. Therefore, at least 1 bit may be used by reducing the maximum number of spatial streams to 8 rather than 16

Coding subfield/UL FEC Coding Type subfield: The coding subfield in PHY layer and the UL FEC Coding Type subfield in MAC layer are utilized to indicate Low-Density Parity Check (LDPC) or binary convolutional code (BCC) used in data field. In the EHT version of Wi-Fi systems (802.11be/Wi-Fi 7) or higher versions, generally only LDPC is applied. Therefore, the coding subfield and the UL FEC Coding Type subfield may be not necessary, as only LDPC will be applied. 1 bit may be used for indicating UMCS and finer MCS information.

Reserved bit: 1 reserved bit of the User Info Field in Trigger Frame in MAC layer is unused for any purpose, so it is used for unequal MCS and Finer MCS.

Increase the length of the User field and the User Info Field: In UHT/Wi-Fi 8/802.11bn systems, more bits may be added to the User field and the User Info Field to support Unequal MCS and Finer MCS. As a result, the length of them is increased. The extra bits may be used as disclosed above to indicate the information for UMCS and finer MCS information.

In some embodiments, signaling is disclosed for indicating additional MCS, UEQM patterns, and 2×LDPC. In some embodiments, the wireless devices encode the MCS field in non-MU-MIMO user field, MU-MIMO user field, an UHR MU PPDU user field, and an UHR user information (info) field in the trigger frame.

In some embodiments, the UEQM pattern field will be in a non-MU-MIMO user field and in an UHR MU PPDU.

In some embodiments, the 2×LDPC field will be in non-MU-MIMO user field, MU-MIMO user field, an UHR MU PPDU user field, and an UHR variant user info field in the trigger frame, if per user indication is encoded in the trigger frame or in the common info field if per common indication is encoded for the trigger frame.

In some embodiments, the 2×LDPC is a per user indication, and is indicated in a non-MU-MIMO user field, MU-MIMO user field, an UHR MU PPDU user field, and an UHR variant user info filed in the trigger frame.

In some embodiments, in a Non-MU-MIMO User Info Field, the total number of bits for the non-MU MIMO user field is the same number as for the EHT user field in a EHT MU PPDU or approximately the same such as 22 bits, 23 bits, or more.

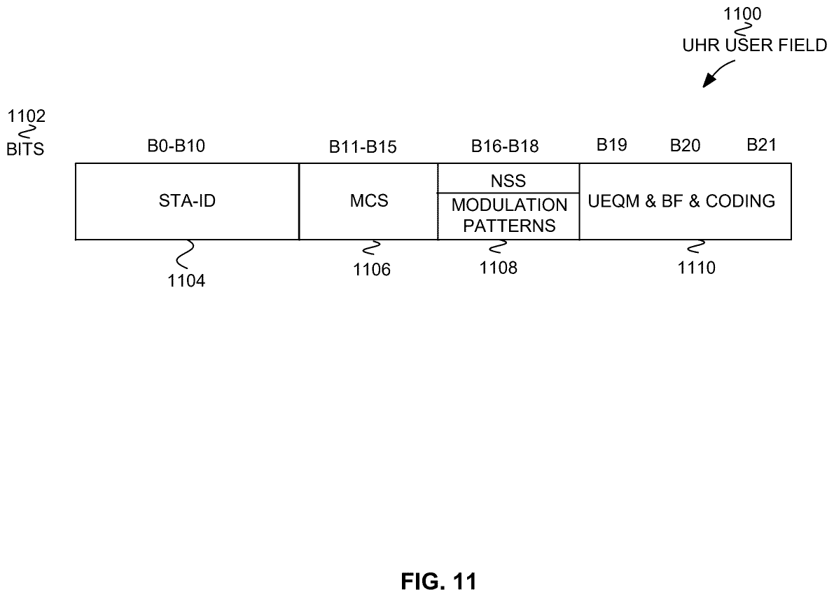

FIG. 11 illustrates a UHR user field 1100, in accordance with some embodiments. The bits 1102 indicate a number of bits in each subfield. The UHR user field 1100 includes a STA-ID 1104 subfield, MCS 1106 subfield, NSS or modulation patterns 1108, and UEQM & BF & CODING 1110 subfield. The number of bits of the UHR user field 1100 may be different such as 23 bits or more.

In some embodiments, the UHR user field 1100 is a non-MU MIMO user information (info) field. The STA-ID 1104 subfield is B0-B10 and indicates the STA-ID as in VHT/IEEE 802.11 be. The MCS 1106 subfield is bits 1102 B11-B15 and indicates the MCS with values of MCS0-MCS15 indicating the same MCS as that in VHT/IEEE 802.11be such as in Table 1.

The NSS 1108 subfield (NSS/Modulation patterns) is bits 1102 B16-B18 and indicates the number of spatial streams (NSS) and supports up to 8 spatial streams as in VHT/IEEE 802.11be. Whether the SS have equal or unequal modulation this is indicated by bits B19-B21 of the UEQM 1110 subfield (UEQM & BFF & CODING). The UEQM 1110 subfield indicates unequal modulation patterns for the SSs supporting up to 8 patterns, if the UEQM 1110 subfield indicates unequal modulation. Example patterns are the following: QAM/QAM-1, QAM/QAM-2, QAM/QAM/QAM-1, QAM/QAM/QAM-2, QAM/QAM-1/QAM-2, QAM/QAM/QAM/QAM-1, QAM/QAM/QAM/QAM-2, and QAM/QAM/QAM-1/QAM-2. The pattern is indicated by the UEQM 1110 subfield in, for example, bits B19-B21.

Table 14 illustrates UEQM example pattern indications.

TABLE 14

| B19-B21 | UEQM pattern |
|---|---|
| 0 0 0 | QAM/QAM-1 |
| 0 0 1 | QAM/QAM-2 |
| 0 1 0 | QAM/QAM/QAM-1 |
| 0 1 1 | QAM/QAM/QAM-2 |
| 1 0 0 | QAM/QAM-1/QAM-2 |
| 1 0 1 | QAM/QAM/QAM/QAM-1 |
| 1 1 0 | QAM/QAM/QAM/QAM-2 |
| 1 1 1 | QAM/QAM/QAM-1/QAM-2 |

In some embodiments, the UEQM 1110 subfield such as bits 1102 B19-B21 are used for to indicate the EQM/UEQM, BF, and coding indication, which will include 2×LDPC as shown in following table as an example. The modulation pattern may then be signaled in the MCS 1106 subfield.

TABLE 15

| UEQM & BF & CODING BIT (Bits 19-21) | | | Description |
|---|---|---|---|
| 0 | 0 | 0 | EQM, No BF, |
| | | | BCC |
| 0 | 0 | 1 | EQM, No BF, |
| | | | 1xLDPC |
| 0 | 1 | 0 | EQM, No BF, |
| | | | 2xLDPC |
| 0 | 1 | 1 | EQM, BF, BCC |
| 1 | 0 | 0 | EQM, BF, |
| | | | 1xLDPC |
| 1 | 0 | 1 | EQM, BF, |
| | | | 2xLDPC |
| 1 | 1 | 0 | UEQM, BF, |
| | | | 1xLDPC |
| 1 | 1 | 1 | UEQM, BF, |
| | | | 2xLDPC |

In some embodiments, B19 of the UHR user field 1100 indicates whether equal or unequal modulation is used. B20 indicates the same things as in EHT/IEEE 802.11be, which may be whether or not there is beamforming (BF).

B21 is set to 0 if 1) BCC is used and the RU or MRU size is smaller than or equal to 242-tone or 2) LDPC with codeword length up to 3888 will be used and RU or MRU size is larger than 242-tone. B21 is set to 1 if LDPC with codeword length up to 1944 is used. In some embodiments, a codeword with length of 3888 will not be used for an RU or a MRU with size smaller than or equal to 242-tone.

In some embodiments, BSS is not supported. B21 is set to 0 if LDPC with codeword length up to 3888 is used. And B21 is set to 1 if LDPC with codeword length up to 1944 is used.

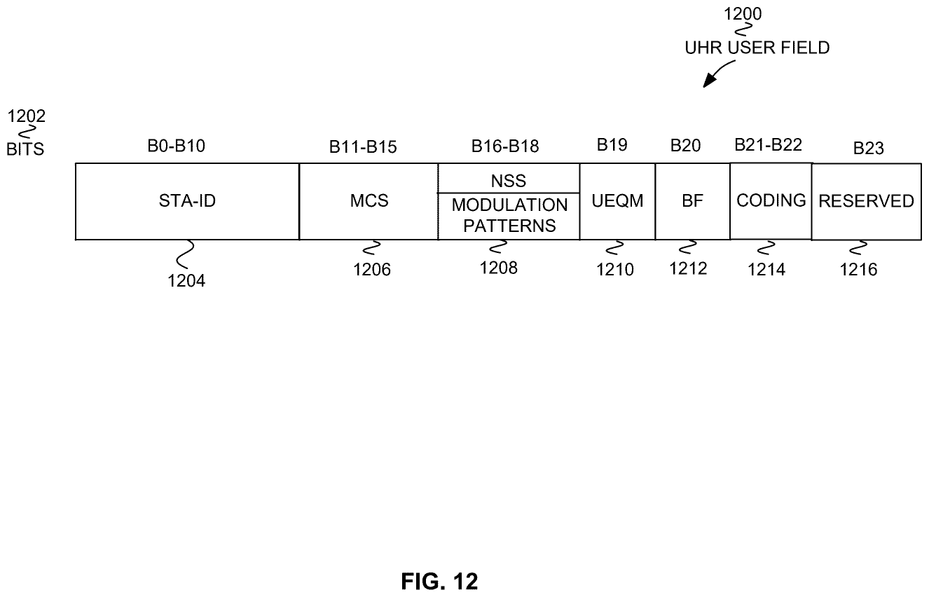

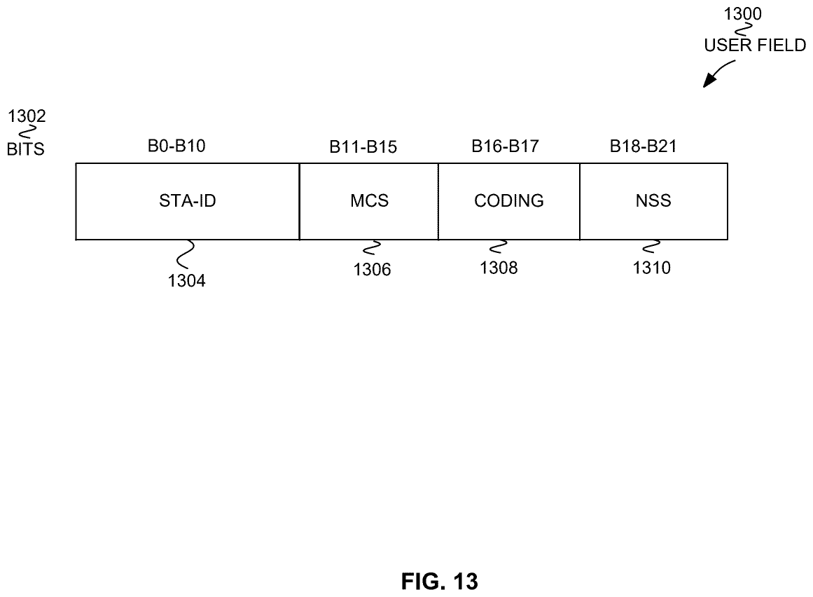

FIG. 12 illustrates a UHR user field 1200, in accordance with some embodiments. In some embodiments, the total number of bits 1202 is for the non-MU MIMO user field (such as UHR user field 1200) will be increased to be 23 or 24 bits. The UHR user field 1200 includes bits 1202 subfield, STA-ID 1204 subfield, MCS 1206 subfield, NSS 1208 subfield, UEQM 1210 subfield, BF 1212 subfield, and coding 1214 subfield.

In some embodiments, B0-B10 (STA-ID 1204 subfield) indicate the STA-ID. In some embodiments, B11-B15 indicate the MCS indication from MCS0 to MCS15 in a same or similar manner as in EHT/IEEE 802.11be such as is illustrated in Table 1.

In some embodiments, B16-B18 (NSS 1208 subfield) indicate NSS supporting up to 8 spatial streams, which may be the same or similar as in EHT/IEEE 802.11be if equal modulation is used. In some embodiments, bits B19-B21 are used to indicate whether equal or unequal modulation is used. If unequal modulation is used, then B16-B18 (NSS 1208 subfield) indicate a modulation pattern where 8 modulation patterns are supported.

In some embodiments, the modulation patterns include: QAM/QAM-1, QAM/QAM-2, QAM/QAM/QAM-1, QAM/QAM/QAM-2, QAM/QAM-1/QAM-2, QAM/QAM/QAM/QAM-1, QAM/QAM/QAM/QAM-2, and QAM/QAM/QAM-1/QAM-2.

In some embodiments, B19 (UEQM 1210 subfield) indicates whether equal or unequal modulation is used. In some embodiments, B20 (BF 1212 subfield) is the same or similar as in EHT/IEEE 802.11be, which indicates whether beamforming is used.

In some embodiments, B21-B22 (coding 1214 subfield) is used to indicate a coding type. Table 16 illustrates an example of indicating the coding type. In some embodiments, B23 is reserved for future use.

### Table 16: Coding Indication.

TABLE 16

| B16-B17 | Coding method |
|---|---|
| 0 0 | BCC |
| 0 1 | LDPC with codeword length up to 1944 |
| 1 0 | LDPC with codeword length up to 3888 or codeword with |
| | length of 3888 is used |
| 1 1 | reserved |

In some embodiments the MU-MIMO User Info Field is encoded as follows for MU-MIMO user information fields. In some embodiments, the number of bits for the MU MIMO user field 1300 is a same number, which is 22 bits, as the EHT user field in a EHT MU PPDU.

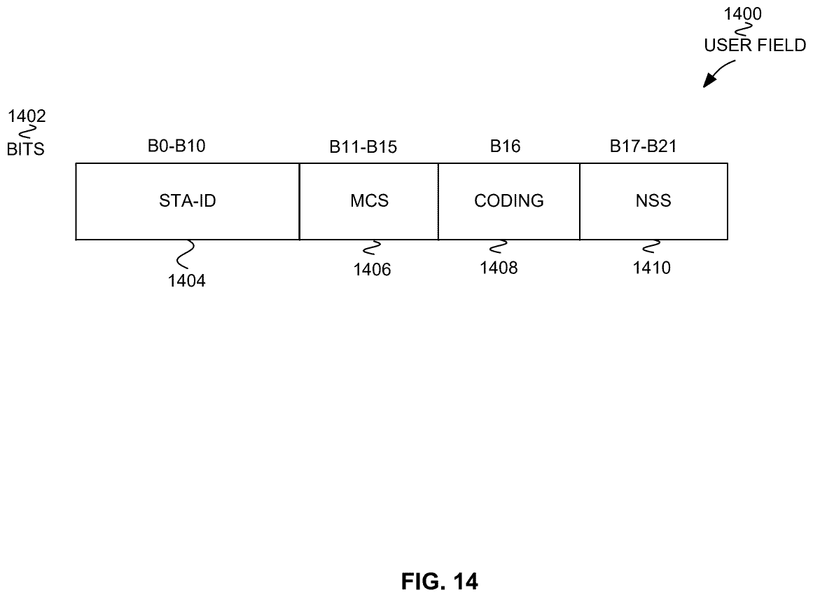

FIG. 13 illustrates a user field 1300, in accordance with some embodiments. The user field 1300 includes STA-ID 1304 subfield, MCS 1306 subfield, coding 1308 subfield, and NSS 1310 subfield where bits 1302 indicates the number of bits for the subfields.

In some embodiments, B0-B10 (STA-ID 1304 subfield) indicates the station identification. B11-B15 (MCS 1306 subfield) indicates the MCS with MCS0 through MCS15 being the same as that in VHT/IEEE 802.11be such as is illustrated in Table 1.

In some embodiments, B16-B17 (coding 1308 subfield) is used to indicate the coding. Table 16 illustrates an example of indicating the coding method.

In some embodiments, B18-B21 (NSS 1310 subfield) is used to indicate the NSS. Table 17 illustrates an example of indicating the NSS.

TABLE 17

| | | Nₛₛ | Nₛₛ | Nₛₛ | Nₛₛ | Nₛₛ | Nₛₛ | Nₛₛ | Nₛₛ | Total | Total |
|---|---|---|---|---|---|---|---|---|---|---|---|
| Nᵤₛₑ | B3 . . . B0 | [1] | [1] | [1] | [1] | [1] | [1] | [1] | [1] | Nₛₛ | entries |
| 2 | 0000-0011 | 1-4 | 1 | | | | | | | 2-5 | 10 |
| | 0100-0110 | 2-4 | 2 | | | | | | | 4-6 | |
| | 0111-1000 | 3-4 | 3 | | | | | | | 6-7 | |
| | 1001 | 4 | 4 | | | | | | | 8 | |
| 3 | 0000-0011 | 1-4 | 1 | 1 | Z | Z | Z | Z | Z | 3-6 | 13 |
| | 0100-0110 | 2-4 | 2 | 1 | Z | Z | Z | Z | Z | 5-7 | |
| | 0111-1000 | 3-4 | 3 | 1 | Z | Z | Z | Z | Z | 7-8 | |
| | 1001 | Reserved | | | | | | | | | |
| | 1010-1100 | 2-4 | 2 | 2 | | | | | | 6-8 | |
| | 1101 | 3 | 3 | 2 | | | | | | 8 | |
| | 1110-1111 | Reserved | | | | | | | | | |
| 4 | 0000-0011 | 1-4 | 1 | 1 | 1 | | | | | 4-7 | 11 |
| | 0100-0110 | 2-4 | 2 | 1 | 1 | | | | | 6-8 | |
| | 0111 | 3 | 3 | 1 | 1 | | | | | 8 | |
| | 1000-1001 | Reserved | | | | | | | | | |
| | 1010-1011 | 2-3 | 2 | 2 | 1 | | | | | 7-8 | |
| | 1100 | 2 | 2 | 2 | 2 | | | | | 8 | |
| | 1111 | Reserved | | | | | | | | | |
| 5 | 0000-0011 | 1-4 | 1 | 1 | 1 | 1 | | | | 5-8 | 7 |
| | 0100-0101 | 2-3 | 2 | 1 | 1 | 1 | | | | 7-8 | |
| | 0110-1001 | Reserved | | | | | | | | | |
| | 1010 | 2 | 2 | 2 | 1 | | | | | 8 | |
| | 1011-1111 | Reserved | | | | | | | | | |
| 6 | 0000-0010 | 1-3 | 1 | 1 | 1 | 1 | 1 | | | 6-8 | 4 |
| | 0011 | Reserved | | | | | | | | | |
| | 0100 | 2 | 2 | 1 | 1 | 1 | 1 | | | 8 | |
| | 0101-1111 | Reserved | | | | | | | | | |
| 7 | 0000-0001 | 1-2 | 1 | 1 | 1 | 1 | 1 | 1 | | 7-8 | 2 |
| | 0010-1111 | Reserved | | | | | | | | | |
| 8 | 0000 | 1 | 1 | 1 | 1 | 1 | 1 | 1 | 1 | 8 | 1 |

| | |
|---|---|
| 0001-1111 | Reserved |

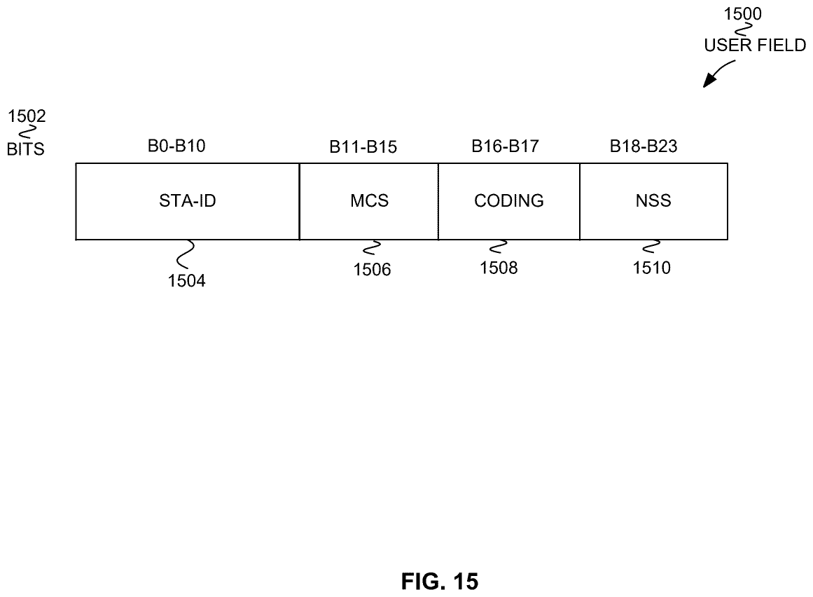

FIG. 14 illustrates a user field 1400, in accordance with some embodiments. User field 1300 and user field 1400 may be used for the same types of PPDUs. The user field 1400 includes STA-ID 1404 subfield, MCS 1406 subfield, coding 1408 subfield, and NSS 1410 subfield where bits 1402 indicates the bits in each subfield.

In some embodiments, B0-B10 indicate the station identification. B11-B15 (MCS 1406 subfield) indicates the MCS indication with MCS0 through MCS15 being the same or similar as that in EHT/IEEE 802.11be such as is illustrated in Table 1.

In some embodiments, B16 will be used for indicating the coding. For example, B16 is set to 0 if 1) BCC is used and the RU or MRU size is smaller than or equal to 242-tone or 2) LDPC with codeword length up to 3888 is used and RU or MRU size is larger than 242-tone. B16 is set to 1 if LDPC with codeword length up to 1944 will is used. In some embodiments, a codeword for LDPC with length of 3888 will not be used for RU or MRU with size smaller than or equal to 242-tone.

In some embodiments, B16 is set to 0: for BCC with RU or MRU less than or equal to 242 tone, or for 2×LDPC with RU or MRU less than 242 tone. B16 is set to 1 for 1×LDPC.

In some embodiments, B17-B21 will be used for the NSS indication. Table 18 illustrates on example of indicating the NSS.

TABLE 18

| | | | | | | | | | | | Total |
|---|---|---|---|---|---|---|---|---|---|---|---|
| | | Nₛₛ | Nₛₛ | Nₛₛ | Nₛₛ | Nₛₛ | Nₛₛ | Nₛₛ | Nₛₛ | Total | en- |
| Nᵤₛₑ | B3 . . . B0 | [1] | [1] | [1] | [1] | [1] | [1] | [1] | [1] | Nₛₛ | tries |
| 2 | 00000-00011 | 1-4 | 1 | | | | | | | 2-5 | 10 |
| | 00100-00110 | 2-4 | 2 | | | | | | | 4-6 | |
| | 00111-01000 | 3-4 | 3 | | | | | | | 6-7 | |
| | 01001 | 4 | 4 | | | | | | | 8 | |
| 3 | 00000-00011 | 1-4 | 1 | 1 | Z | Z | Z | Z | Z | 3-6 | 13 |
| | 00100-00110 | 2-4 | 2 | 1 | Z | Z | Z | Z | Z | 5-7 | |
| | 00111-01000 | 3-4 | 3 | 1 | Z | Z | Z | Z | Z | 7-8 | |
| | 01001 | Reserved | | | | | | | | | |
| | 01010-01100 | 2-4 | 2 | 2 | | | | | | 6-8 | |
| | 01101 | 3 | 3 | 2 | | | | | | 8 | |
| | 01110-01111 | Reserved | | | | | | | | | |
| 4 | 00000-00011 | 1-4 | 1 | 1 | 1 | | | | | 4-7 | 11 |
| | 00100-00110 | 2-4 | 2 | 1 | 1 | | | | | 6-8 | |
| | 00111 | 3 | 3 | 1 | 1 | | | | | 8 | |
| | 01000-01001 | Reserved | | | | | | | | | |
| | 01010-01011 | 2-3 | 2 | 2 | 1 | | | | | 7-8 | |
| | 01100-10011 | Reserved | | | | | | | | | |
| | 10100 | 2 | 2 | 2 | 2 | | | | | 8 | |
| | 10101-11111 | Reserved | | | | | | | | | |
| 5 | 00000-00011 | 1-4 | 1 | 1 | 1 | 1 | | | | 5-8 | 7 |
| | 00100-00101 | 2-3 | 2 | 1 | 1 | 1 | | | | 7-8 | |
| | 00110-01001 | Reserved | | | | | | | | | |
| | 01010 | 2 | 2 | 2 | 1 | | | | | 8 | |
| | 01011-10000 | Reserved | | | | | | | | | |
| 6 | 00000-00010 | 1-3 | 1 | 1 | 1 | 1 | 1 | | | 6-8 | 4 |
| | 00011 | Reserved | | | | | | | | | |
| | 00100 | 2 | 2 | 1 | 1 | 1 | 1 | | | 8 | |
| | 00101-10101 | Reserved | | | | | | | | | |
| 7 | 00000-00001 | 1-2 | 1 | 1 | 1 | 1 | 1 | 1 | | 7-8 | 2 |
| | 00010-10001 | Reserved | | | | | | | | | |
| 8 | 00000 | 1 | 1 | 1 | 1 | 1 | 1 | 1 | 1 | 8 | 1 |

| | |
|---|---|
| 00001-11010 | Reserved |

FIG. 15 illustrates a user field 1500, in accordance with some embodiments. The user field 1500 may be used with the same types of PPDU as user field 1300 and user field 1400. The user field 1500 includes STA-ID 1504 subfield, MCS 1506 subfield, coding 1508 subfield, and NSS 1510 subfield where bits 1502 indicates the bits in each subfield.

A total number of bits for the MU MIMO user field 1500 is increased by 2 bits, in accordance with some embodiments.

B0-B10 (STA-ID 1504 subfield) indicate the station identification. B11-B15 (MCS 1506 subfield) indicate the MCS with MCS0 through MCS15 indicating the same MSC as that in EHT/IEEE 802.11be such as is illustrated in Table 1.

B16-B17 (coding 1508 subfield) is used for indicating the coding. Table 16 illustrates an example of the coding. B18-B23 (NSS 1510 subfield) is used for the NSS indication, which may be the same or similar as in EHT/IEEE 802.11be.

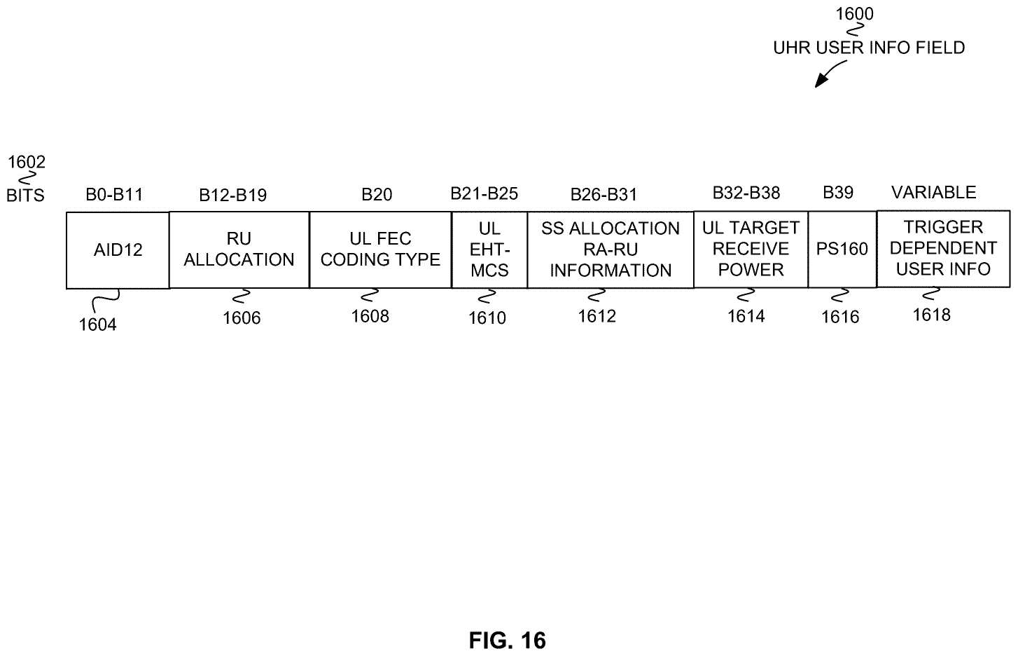

The following are UHR variant user information fields. FIG. 16 illustrates an UHR user info field 1600, in accordance with some embodiments. The UHR user info field 1600 includes an AID12 1604 subfield, an RU allocation 1606 subfield, an UL FEC coding type 1608 subfield, an UL EHT-MCS 1610 subfield, an SS allocation RA-RU information 1612 subfield, an UL target receive power 1614 subfield, a PS160 1616 subfield, and a trigger dependent user info 1618 subfield with the corresponding bits 1602.

B0-B19 (AID12 1604 subfield and RU allocation 1606 subfield) may be the same or similar as in the UHR user info field of EHT/IEEE 802.11be.

In some embodiments, B20 (UL FEC coding type 1608 subfield) is used to indicate what the UL FEC Coding Type is to be. A 0 is used if 1) BCC is to be used and the RU or MRU size is smaller than or equal to 242-tone or 2) LDPC is to be used with a codeword length up to 3888 and the RU or MRU size is larger than 242-tone. A 1 is used if LDPC is to be used with a codeword length up to 1944.

In some embodiments, B20 is set to 0 for BCC with RU or MRU less than 242 tones or for 2×LDPC with RU or MRU less than 242 tones. And B20 is set to 1 for 1×LDPC.

In some embodiments, B21-B25 (UL EHT-MCS) are used to indicate the MCS to be used, with MCS0 through MCS15 the same or similar as in EHT/IEEE 802.11be such as is illustrated in Table 1.

SS allocation RA-RU information 1612 subfield is the same or similar as in EHT/IEEE 802.11be. UL target receive power 1614 subfield is the same or similar as in EHT/IEEE 802.11be. PS160 1616 subfield is the same or similar as in EHT/IEEE 802.11be. The trigger dependent user info 1618 subfield may be the same or similar as used in EHT/IEEE 802.11be.

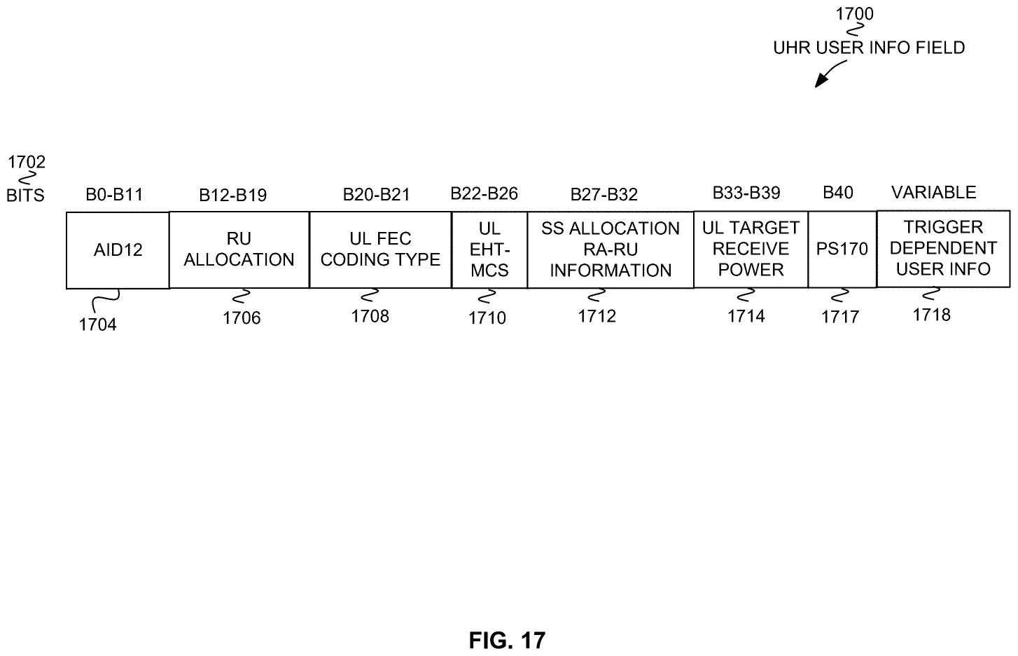

The following are UHR variant user information fields. FIG. 17 illustrates an UHR user info field 1700, in accordance with some embodiments. The UHR user info field 1700 includes an AID12 1704 subfield, an RU allocation 1706 subfield, an UL FEC coding type 1708 subfield, an UL EHT-MCS 1710 subfield, an SS allocation RA-RU information 1712 subfield, an UL target receive power 1714 subfield, a PS160 1716 subfield, and a trigger dependent user info 1718 subfield with the corresponding bits 1702.

B0-B19 (AID12 1704 subfield and RU allocation 1706 subfield) may be the same or similar as in the UHR user info field of EHT/IEEE 802.11be.

B20-B21 (UL FEC coding type 1708) is used for UL FEC coding type. Table 16 illustrates an example of indicating or signaling the UL FEC coding type.

B22-B26 are used to indicate the MCS, with MCS0 through MCS15 being the same or similar as in EHT/IEEE 802.11be such as illustrated in Table 1.

SS allocation RA-RU information 1712 subfield is the same or similar as in EHT/IEEE 802.11be, although the bits 1702 assigned may be different. UL target receive power 1714 subfield is the same or similar as in EHT/IEEE 802.11be, although the bits 1702 assigned may be different. PS160 1716 subfield is the same or similar as in EHT/IEEE 802.11be, although the bits 1702 assigned may be different. The trigger dependent user info 1718 subfield may be the same or similar as used in EHT/IEEE 802.11be, although the bits 1702 assigned may be different.

In some embodiments, bits are used from the AID field, e.g., AID12 1004, 1604, 1704, or STA-ID 904, 1104, 1204, 1304, 1404. In the embodiments above (e.g., FIGS. 11-17), the additional indication bits required by UHR come from reserved bits and combinations of fields. Another source of indication bits may come from the original AID field or a coding bit by removing the BCC case.

The original AID field has 12 bits. It can be viewed as a device ID or a short version of the full MAC address that has 48 bits. It is uncommon for a cell to have more than one thousand devices, which require a 10-bit address. Therefore, an AID with 9, 10 or 11 bits should be enough for most cases. As a result, we can shorten the existing AID field by 1 or 2 or more bits and use the bits for the indication of UHR features like unequal modulation, modulation patterns, and 2× lifted LDPC, which are additional to the previous HE and EHT. Using the bits from the original AID field may maximize the backward compatibility. For example, we can keep the existing fields as unchanged as possible and add additional field or sub-field for the additional UHR indications so that we don't need to combine several fields from the existing and/or new UHR indications to squeeze out usable bits. In some embodiments, the AID field or AID12 field is only 9, 10, or 11 bits and these bits are used to indicate unequal modulation, modulation patterns, and/or coding such as 2×LDPC.

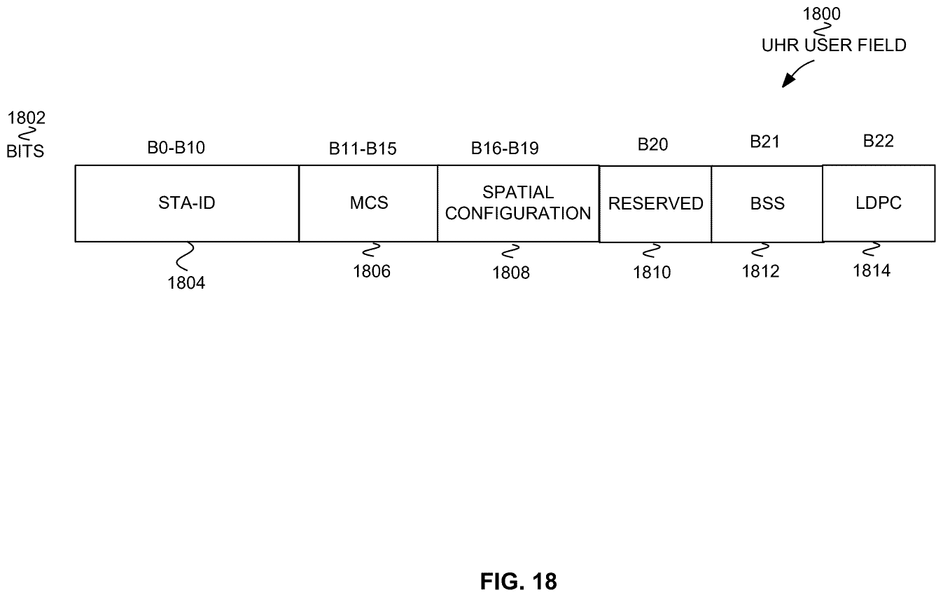

FIG. 18 illustrates UHR user field 1800, in accordance with some embodiments. The UHR user field 1800 may be used as a MU-MIMO user field in an UHR MU PPDU. The UHR user field 1800 includes STA-ID 1804 subfield, MCS 1806 subfield, spatial configuration 1808 subfield, reserved 1810 subfield, BSS 1812 subfield, and LDPC 1814 subfield. The STA-ID 1804 subfield may be a same identification as used in UHT/IEEE 802.11be. The MCS 1806 indicates a MCS for the user portion of the UHR MU PPDU. The MCS 1806 subfield may indicates a MCS in accordance with Table 1, Table 2, Table 3, and/or with a new encoding. For example, the MCS 1806 subfield may be in accordance with Table 1 and indicate different MCSs above 15. The spatial configuration 1808 subfield indicates an allocation of a spatial streams such as is disclosed in Table 17 and Table 18. In some embodiments, the spatial configuration 1808 subfield indicates an allocation of spatial streams and a pre-defined pattern of UMCS such as is disclosed herein or another encoding of a pre-defined pattern of UMCS.

The reserved 1810 subfield is reserved. The BSS 1812 subfield selects between a first BSS or a second BSS. If the UL/DL field in the U-SIG field is set to 0, the PPDU type and compression mode field in the U-SIG field is set to 2 and the COBF/COSR field in the U-SIG field is set to 0. B21 is used to indicate whether the current STA-ID indicated by the STA-ID 1804 subfield is for a first BSS or a second BSS in COBF when B21 is 0, the first BSS is associated with the BSS color field in the U-SIG field of the UHR MU PPDU and when B21 is 1, the second BSS is associated with the BSS color 2 field of the U-SIG field. If U-SIG field does not indicate a selection between the first BSS and the second BSS, then B21 is set to 1 and is reserved. The LDPC 1814 subfield indicates either 1×LDPC or 2×LDPC for the corresponding STA or user indicated by the STA0ID 1804 subfield. For example, a value of 0 indicates 1×LDPC and a value of 1 indicates 2×LDPC.

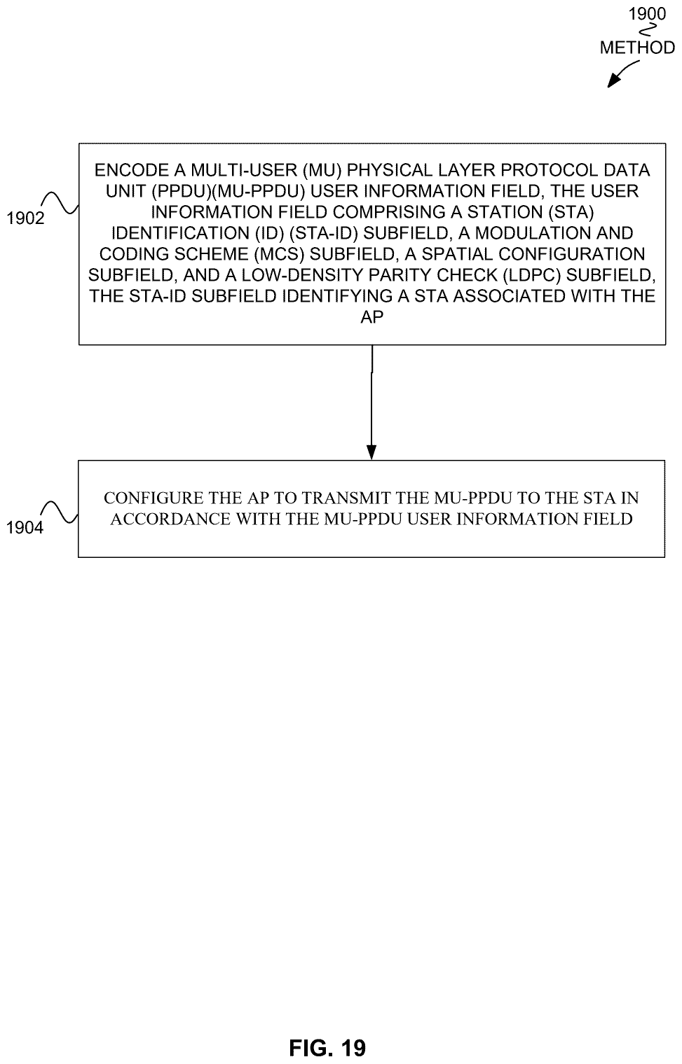

FIG. 19 illustrates a method 1900 for signaling with unequal and finer MCSs, in accordance with some embodiments. The method 1900 begins at operation 1902 with encoding a multi-user (MU) physical layer protocol data unit (PPDU) (MU-PPDU) user information field, the user information field comprising a station (STA) identification (ID) (STA-ID) subfield, a modulation and coding scheme (MCS) subfield, a spatial configuration subfield, and a Low-Density Parity Check (LDPC) subfield, the STA-ID subfield identifying a STA associated with the AP. For example, an apparatus of an AP 502 or AP MLD 808, or an apparatus of a STA 504 or non-AP MLD 809 may configure a user information field in accordance with the UHR user field 1800 of FIG. 18 or another user information field disclosed herein.

The method 1900 may configure at operation 1904 with the AP to transmitting the MU-PPDU to the STA in accordance with the MU-PPDU user information field. For example, an apparatus of an AP 502 or AP MLD 808, or an apparatus of a STA 504 or non-AP MLD 809 may transmit a PPDU after encoding a user information field in accordance with the UHR user field 1800 of FIG. 18 or another user information field disclosed herein.

The method 1900 may be performed by a transmitter which may be an apparatus for a STA 504, an apparatus of a non-AP MLD 809, an apparatus of an AP 502, an apparatus of an AP MLD 808, an apparatus of a non-AP STA1 818, an apparatus of an AP1 830, and/or another device or apparatus disclosed herein. The method 1900 may include one or more additional operations including intermediate operations. The method 1900 may be performed in a different order. One or more of the operations of method 1900 may be optional. Method 1900 may be performed by UHR wireless devices.

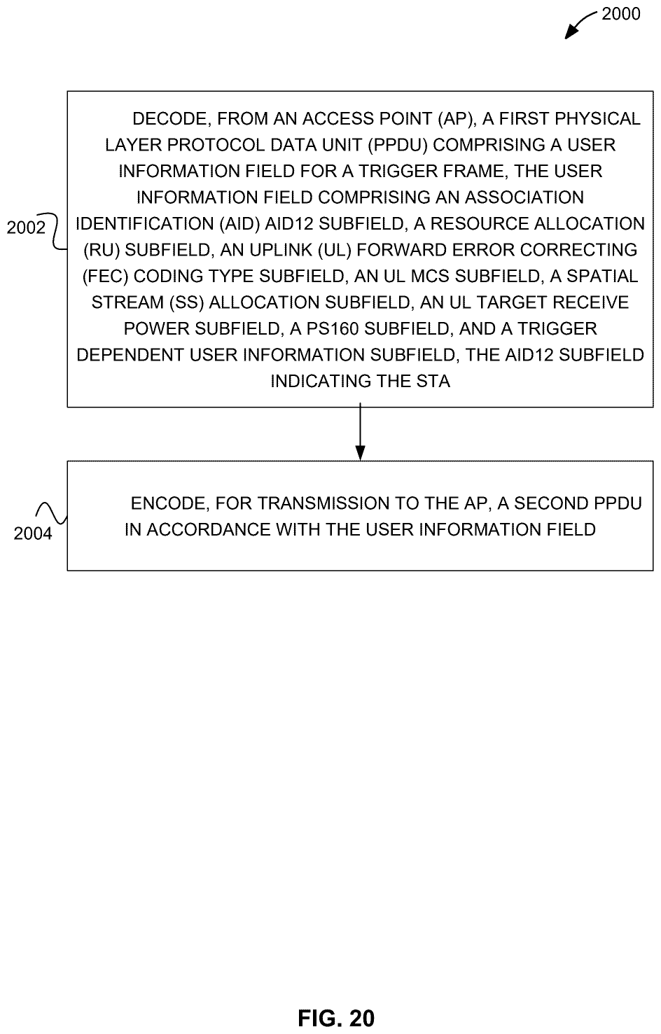

FIG. 20 illustrates a method 2000 for signaling with unequal and finer MCSs, in accordance with some embodiments. The method 2000 begins at operation 2002 with decoding, from an access point (AP), a first physical layer protocol data unit (PPDU) comprising a user information field for a trigger frame, the user information field comprising an association identification (AID) AID12 subfield, a resource allocation (RU) subfield, an uplink (UL) forward error correcting (FEC) coding type subfield, an UL MCS subfield, a spatial stream (SS) allocation subfield, an UL target receive power subfield, a PS160 subfield, and a trigger dependent user information subfield, the AID12 subfield indicating the STA. For example, an apparatus of an AP 502 or AP MLD 808, or an apparatus of a STA 504 or non-AP MLD 809 may configure a user information field in accordance with the UHR user info field 1600 of FIG. 16, the UHR user info field 1700 of FIG. 17, or another user information field disclosed herein.

The method 2000 continues at operation 2004 with encoding, for transmission to the AP, a second PPDU in accordance with the user information field. For example, an apparatus of an AP 502 or AP MLD 808, or an apparatus of a STA 504 or non-AP MLD 809 may transmit a PPDU after encoding a user information field in accordance with the UHR user info field 1600 of FIG. 16, the UHR user info field 1700, or another user information field disclosed herein.

The method 2000 may be performed by a transmitter which may be an apparatus for a STA 504, an apparatus of a non-AP MLD 809, an apparatus of an AP 502, an apparatus of an AP MLD 808, an apparatus of a non-AP STA1 818, an apparatus of an AP1 830, and/or another device or apparatus disclosed herein. The method 2000 may include one or more additional operations including intermediate operations. The method 2000 may be performed in a different order. One or more of the operations of method 2000 may be optional. Method 2000 may be performed by UHR wireless devices.

The fields and subfields may be termed differently. For example, a user field may be termed a user information field or visa-versa. The size of the fields and subfields may be different. The number of fields or subfields may be different. The number of field or subfields may be in a different order. The number of bits in the fields and the subfields may be different.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus for an access point (AP), the apparatus comprising memory; and processing circuitry coupled to the memory, the processing circuitry configured to:
encode a multi-user (MU) multi-input multiple output (MIMO) physical layer protocol data unit (PPDU) (MU MIMO PPDU), the MU MIMO PPDU comprising a user field, the user field comprising a station (STA) identification (ID) (STA-ID) subfield, a modulation and coding scheme (MCS) subfield, a spatial configuration subfield, and a Low-Density Parity Check (LDPC) subfield, the STA-ID subfield identifying a STA associated with the AP; and
configure the AP to transmit the MU MIMO PPDU to the STA in accordance with the user field.

2. The apparatus of claim 1, wherein the LDPC subfield indicates either 1×LDPC or 2×LDPC for the STA.

3. The apparatus of claim 1, wherein the MCS subfield is 5 bits and the MCS subfield indicates IEEE 802.11be MCS values of 0, 1, 2, 3, 4, 5, 6, 7, 8, 9, 10, 11, 12, 13, and 15, and indicates additional MCSs for values above 15.

4. The apparatus of claim 1, wherein the spatial configuration subfield indicates a number of spatial stream allocations for the STA.

5. The apparatus of claim 1, wherein the STA-ID subfield is bits 0 through 10 of the user field, the MCS subfield is bits 11 through 15 of the user field, the spatial configuration subfield is bits 16 through 19 of the user field, and the LDPC subfield is bit 22 of the user field.

6. The apparatus of claim 1, wherein the STA-ID subfield is a first STA-ID subfield, the MCS subfield is a first MCS subfield, the user field is a first user field, and wherein the processing circuitry is further configured to:
encode a non-MU MIMO PPDU, the non-MU MIMO PPDU comprising a second user field, the second user field comprising a second STA-ID subfield, a second MCS subfield, a number of spatial streams (NSS) subfield, an unequal modulation (UEQM) subfield, and a Low-Density Parity Check (LDPC) indication subfield, the second STA-ID subfield identifying the STA associated with the AP; and
configure the AP to transmit the non-MU MIMO PPDU to the STA.

7. The apparatus of claim 6, wherein the UEQM subfield indicates whether equal or unequal modulation is used for the spatial streams.

8. The apparatus of claim 6, wherein the user field further comprises a UEQM pattern subfield, the UEQM pattern subfield indicating a UEQM pattern for the spatial streams indicated by the NSS subfield, the UEQM pattern indicating a relative reduction of a modulation order of a next spatial stream of the spatial streams indicated by the NSS subfield, wherein UEQM patterns for four spatial streams comprise Quadrature Amplitude Modulation QAM/QAM/QAM-1/QAM-2 and QAM/QAM/QAM/QAM-1, and wherein the UEQM patterns for two spatial streams comprise: QAM/QAM-1, wherein −1 and −2 indicate the relative reduction of the modulation order with respect to aa modulation order of a first spatial stream of the spatial streams.

9. The apparatus of claim 6, wherein the second user field further comprises a beamforming subfield, the beamforming subfield indicating whether beamforming is used.

10. The apparatus of claim 6, wherein the LDPC indication subfield indicates a coding type of a plurality of coding types, the plurality of coding types comprising: 1×LDPC and 2×LDPC.

11. The apparatus of claim 6, wherein the MCS subfield is 5 bits, the MCS subfield indicates a coding rate for the spatial streams indicated by the NSS subfield and a modulation order for a first spatial stream of the spatial streams, wherein the MCS subfield indicates IEEE 802.11be MCS values of 0, 1, 2, 3, 4, 5, 6, 7, 8, 9, 10, 11, 12, 13, and 15, and indicates additional MCSs for values above 15.

12. The apparatus of claim 6, wherein the STA-ID subfield is bits 0 through 10 of the second user field, the MCS subfield is bits 11 through 15 of the user field, the NSS subfield is bits 16 through 18 of the user field, the UEQM subfield is bit 19, and wherein the second user field is 23 bits.

13. The apparatus of claim 1, wherein the processing circuitry is further configured to:
encode a ultra-high reliability (UHR) user information (info) field for a trigger frame, the UHR user info field comprising an AID12 subfield, a resource allocation (RU) subfield, an uplink (UL) forward error correcting (FEC) coding type subfield, an UL MCS subfield, a spatial stream (SS) allocation subfield, an UL target receive power subfield, a PS160 subfield, and a trigger dependent user information subfield, the AID12 subfield indicating the STA; and
configure the AP to transmit the trigger frame to the STA.

14. The apparatus of claim 13, wherein the AID12 subfield and the RU allocation subfield are same subfields as disclosed in IEEE 802.11be and a total number of bits of the user information field is a same number as a total number of bits of the user information field disclosed in IEEE 802.11be.

15. The apparatus of claim 13, wherein the UL MCS subfield indicates same MCSs as IEEE 802.11be for values of 0, 1, 2, 3, 4, 5, 6, 7, 8, 9, 10, 11, 12, 13, and 15, and indicates additional MCSs for values above 15.

16. The apparatus of claim 13, wherein a value of 0 of the UL FEC coding type subfield indicates Binary Convolutional Coding (BCC) for an RU or an MRU indicated by the RU allocation subfield less than or equal to 242 tones or 2× Low-Density Parity Check (LDPC) for the RU or the MRU indicated by the RU allocation subfield greater than 242 tones, and a value of 1 of the UL FEC coding type subfield indicates 1×LDPC.

17. The apparatus of claim 1, further comprising transceiver circuitry coupled to the processing circuitry, wherein the transceiver circuitry is coupled to two or more microstrip antennas for receiving signaling in accordance with a multiple-input multiple-output (MIMO) technique, or the transceiver circuitry is coupled to the processing circuitry, the transceiver circuitry coupled to two or more patch antennas for receiving signaling in accordance with a multiple-input multiple-output (MIMO) technique.

18. A non-transitory computer-readable storage medium including instructions that, when processed by one or more processors, configure an apparatus for an access point (AP), to perform operations comprising:
encode a multi-user (MU) multi-input multiple output (MIMO) physical layer protocol data unit (PPDU) (MU MIMO PPDU, the MU MIMO PPDU comprising a user field, the user field comprising a station (STA) identification (ID) (STA-ID) subfield, a modulation and coding scheme (MCS) subfield, a spatial configuration subfield, and a Low-Density Parity Check (LDPC) subfield, the STA-ID subfield identifying a STA associated with the AP; and
configure the AP to transmit the MU MIMO PPDU to the STA in accordance with the user field.

19. The non-transitory computer-readable storage medium of claim 18, wherein the LDPC subfield indicates either 1×LDPC or 2×LDPC for the STA.

20. An apparatus for a station (STA), the apparatus comprising memory; and processing circuitry coupled to the memory, the processing circuitry configured to:
decode, from an access point (AP), a first physical layer protocol data unit (PPDU) comprising a user information field for a trigger frame, the user information field comprising an association identification (AID) AID12 subfield, a resource allocation (RU) subfield, an uplink (UL) forward error correcting (FEC) coding type subfield, an UL MCS subfield, a spatial stream (SS) allocation subfield, an UL target receive power subfield, a PS160 subfield, and a trigger dependent user information subfield, the AID12 subfield indicating the STA; and
encode, for transmission to the AP, a second PPDU in accordance with the user information field.
